(19) United States
(12) Patent Application Publication
(10) Pub. No.: US 2025/0081698 A1
(43) Pub. Date: Mar. 6, 2025

(54) DISPLAY DEVICE AND METHOD OF MANUFACTURING THE SAME

(71) Applicant: Samsung Display Co., LTD., Yongin-si (KR)

(72) Inventors: Seongwon KIM, Yongin-si (KR); Hosik SHIN, Yongin-si (KR); Kyungmin KIM, Yongin-si (KR); Junhyeong PARK, Yongin-si (KR)

(21) Appl. No.: 18/805,369

(22) Filed: Aug. 14, 2024

(30) Foreign Application Priority Data
Sep. 5, 2023 (KR) 10-2023-0117431

(51) Int. Cl. H01L 33/62; H01L 25/075; H01L 33/00

(52) U.S. Cl. CPC H10H 20/857; H01L 25/0753; H10H 20/018; H10H 20/0364

(57) ABSTRACT

A display device includes a first film, and a display panel disposed on the first film and including a display portion, a driver portion, and a frame portion, which are sequentially arranged in a first direction, wherein the display portion includes a plurality of first island portions spaced apart from each other and including light-emitting elements, the driver portion includes a plurality of second island portions spaced apart from each other and on which drivers that provide electrical signals to the light-emitting elements are arranged, the frame portion includes a plurality of third island portions spaced apart from each other in a second direction crossing the first direction, and an elongation rate of the display portion, an elongation rate of the driver portion, and an elongation rate of the frame portion are different from each other.

This application claims priority to Korean Patent Application No. 10-2023-0117431, filed on Sep. 5, 2023, and all the benefits accruing therefrom under 35 U.S.C. § 119, the content of which in its entirety is herein incorporated by reference.

### BACKGROUND

### 1. Field

Embodiments relate to a device and a method, and more particularly, to a display device and a method of manufacturing the display device.

### 2. Description of the Related Art

With the development of display devices that visually display electrical signals, various display devices having excellent characteristics such as thinness, weight reduction, and relatively low power consumption have been introduced. For example, flexible display devices that may be folded or rolled into a roll shape are being introduced. Recently, research and development of stretchable display devices that may change into various forms are actively underway.

### SUMMARY

Embodiments include a flexible display device, e.g., a stretchable display device.

Additional features will be set forth in part in the description which follows and, in part, will be apparent from the description, or may be learned by practice of the presented embodiments of the disclosure.

An embodiment of the disclosure, a display device includes a first film, and a display panel disposed on the first film and including a display portion, a driver portion, and a frame portion, which are sequentially arranged in a first direction, wherein the display portion includes a plurality of first island portions spaced apart from each other and including light-emitting elements, the driver portion includes a plurality of second island portions spaced apart from each other, and on which drivers that provide electrical signals to the light-emitting elements are arranged, the frame portion includes a plurality of third island portions spaced apart from each other in a second direction crossing the first direction, and an elongation rate of the display portion, an elongation rate of the driver portion, and an elongation rate of the frame portion are different from each other.

In an embodiment, the elongation rate of the driver portion may be greater than the elongation rate of the frame portion in the first direction.

In an embodiment, the elongation rate of the frame portion may be greater than the elongation rate of the driver portion in the second direction.

In an embodiment, one of the plurality of second island portions may be extended to one of the plurality of third island portions.

In an embodiment, at least two of the plurality of second island portions may be extended to one of the plurality of third island portions.

In an embodiment, different numbers of second island portions among the plurality of second island portions may be extended to at least two of the plurality of third island portions.

In an embodiment, with respect to a center line between two adjacent third island portions of the plurality of third island portions, two adjacent second island portions of the plurality of second island portions may be symmetrical to each other.

In an embodiment, at least two of the plurality of third island portions may have different shapes from each other.

In an embodiment, at least one of the plurality of third island portion portions may include a plurality of sawtooth portions spaced apart from each other in the second direction, and a connecting portion extended from the plurality of sawtooth portions in the first direction so that the plurality of sawtooth portions is extended to each other.

In an embodiment, a length of each of third island portions in the second direction may among the plurality of third island portions be greater than a length of each of second island portions in the second direction among the plurality of second island portions.

In an embodiment, the first film may include at least one of polydimethylsiloxane (“PDMS”) and polyurethane (“PU”).

In an embodiment, the display device may further include a second film disposed on the display panel.

In an embodiment, the second film may include a same material as that of the first film.

An embodiment of the disclosure, a method of manufacturing a display device includes disposing, on a support substrate, a display panel including a display portion, a driver portion, and an outer portion, which are sequentially arranged in a first direction, disposing a support film on the display panel, removing the support substrate from the display panel, disposing the display panel on a first film, removing the support film from the display panel, and cutting the outer portion along a cutting line, wherein the outer portion includes a plurality of sawtooth portions spaced apart from each other in a second direction crossing the first direction, and a connecting portion extended from the plurality of sawtooth portions in the first direction so that the plurality of sawtooth portions is extended to each other, wherein the cutting line overlaps at least one of a plurality of sawtooth openings defining a space between the plurality of sawtooth portions.

In an embodiment, the cutting line may overlap an end of at least one of the plurality of sawtooth openings.

In an embodiment, the cutting line may be spaced apart from at least one of the plurality of sawtooth openings.

In an embodiment, the plurality of sawtooth openings may include a first sawtooth opening and a second sawtooth opening having a length greater in the first direction than a length of the first sawtooth opening.

In an embodiment, the cutting line may be spaced apart from the first sawtooth opening and may overlap the second sawtooth opening.

In an embodiment, the first film may include at least one of PDMS and PU.

In an embodiment, the support film may have a higher modulus than a modulus of the first film.

In an embodiment, the support film may include a polyethylene terephthalate (“PET”) material.

In an embodiment, the method may further include arranging a second film on the display panel.

In an embodiment, the arranging the second film on the display panel may be performed between the removing the support film from the display panel and the cutting the outer portion along the cutting line.

In an embodiment, the arranging the support film on the display panel may include arranging the support film on the second film.

In an embodiment, the second film may include a same material as that of the first film.

Other features and advantages than the above-described features and advantages will be apparent from a detailed description, the claims, and the drawings.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a perspective view schematically showing an embodiment of a stretchable display device;

FIGS. 2A and 2B are perspective views showing the stretchable display device of FIG. 1 stretched in a first direction;

FIG. 2C is a perspective view showing the stretchable display device of FIG. 1 stretched in a second direction;

FIG. 2D is a perspective view showing the display device of FIG. 1 stretched in the first and second directions;

FIG. 2E is a perspective view showing the stretchable display device of FIG. 1 stretched in a third direction;

FIG. 3 is a plan view schematically showing an embodiment of a stretchable display device;

FIG. 4A is an enlarged plan view of an embodiment of an area IV of FIG. 3 as part of a stretchable display device;

FIG. 4B is an enlarged plan view of an embodiment of an area IV of FIG. 3 as part of a stretchable display device;

FIG. 4C is an enlarged plan view of an embodiment of an area IV of FIG. 3 as part of a stretchable display device;

FIG. 5 is a cross-sectional view schematically showing an embodiment of a first island portion and a first bridge portion, arranged in a display area of a stretchable display device;

FIGS. 6A to 6C are equivalent circuit diagrams of an embodiment of a sub-pixel of a stretchable display device;

FIG. 7A is a cross-sectional view schematically showing an embodiment of a light-emitting element of a stretchable display device;

FIG. 7B is a cross-sectional view schematically showing an embodiment of a light-emitting element of a stretchable display device;

FIG. 8 is a schematic cross-sectional view of an embodiment of a portion of a stretchable display device;

FIG. 9 is a schematic plan view of an embodiment of a portion of a stretchable display device;

FIGS. 10A and 10B are schematic plan views of an embodiment of a portion of a stretchable display device;

FIG. 11 is a schematic plan view of an embodiment of a portion of a stretchable display device;

FIG. 12A is a schematic cross-sectional view of an embodiment of a portion of a stretchable display device;

FIG. 12B is a schematic plan view of an embodiment of a portion of a stretchable display device;

FIGS. 12C and 12D are schematic cross-sectional views of an embodiment of a portion of a stretchable display device;

FIG. 12E is a schematic plan view of an embodiment of a portion of a stretchable display device;

FIGS. 12F and 12G are schematic cross-sectional views of an embodiment of a portion of a stretchable display device;

FIG. 13 is a schematic cross-sectional view of an embodiment of a portion of a stretchable display device;

FIGS. 14A to 14E are schematic cross-sectional views of an embodiment of a portion of a stretchable display device;

FIGS. 15A to 15D are schematic cross-sectional views of an embodiment of a portion of a stretchable display device;

FIG. 16 is a schematic plan view of an embodiment of a portion of a stretchable display device;

FIGS. 17A and 17B are schematic plan views of an embodiment of a portion of a stretchable display device;

FIGS. 18A and 18B are schematic plan views of an embodiment of a portion of a stretchable display device; and

FIGS. 19A to 19G are perspective views schematically showing embodiments of an electronic device including a stretchable display device.

### DETAILED DESCRIPTION

Reference will now be made in detail to embodiments, embodiments of which are illustrated in the accompanying drawings, wherein like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

The disclosure is subject to various modifications and may have many embodiments, certain of which are illustrated in the drawings and further described in the detailed description. The effects and features of the disclosure, and methods of achieving them will become clear with reference to the embodiments described below in detail together with the drawings. However, the disclosure is not limited to the embodiments described herein and may be implemented in various forms.

Hereinafter, embodiments will be described in detail with reference to the accompanying drawings, and when being described with reference to the drawings, the same or corresponding components are given the same reference numerals, and duplicate descriptions thereof will be omitted.

In the following embodiments, the terms first, second, etc., are not intended to be limiting, however are used to distinguish one component from another.

In the following embodiments, the singular expression includes the plural unless the context clearly indicates otherwise.

In the following embodiments, the terms including or that has, etc., are intended to imply the presence of the recited features or components and do not preclude the possibility of the addition of one or more other features or components.

In the following embodiments, when a portion of a film, area, component, etc., is the to be over or on top of another portion, this includes not only when it is directly on top of the other portion, but also when there are other films, areas, components, etc., arranged therebetween.

In the drawings, components may be exaggerated or reduced in size for ease of illustration. For example, the size and thickness of each configuration shown in the drawings are arbitrary for purposes of illustration and the disclosure is not necessarily limited to those shown.

In the following embodiments, the terms x-axis, y-axis, and z-axis are not limited to, however, may be interpreted in a broad sense to include three axes in a Cartesian coordinate system. For example, the x-axis, y-axis, and z-axis may be orthogonal to each other, however, may also refer to different directions that are not orthogonal to each other.

In some embodiments, a particular sequence of processes may be performed in a different order than that described. For example, two processes described in succession may be performed substantially simultaneously, or may be performed in the opposite order from the order described.

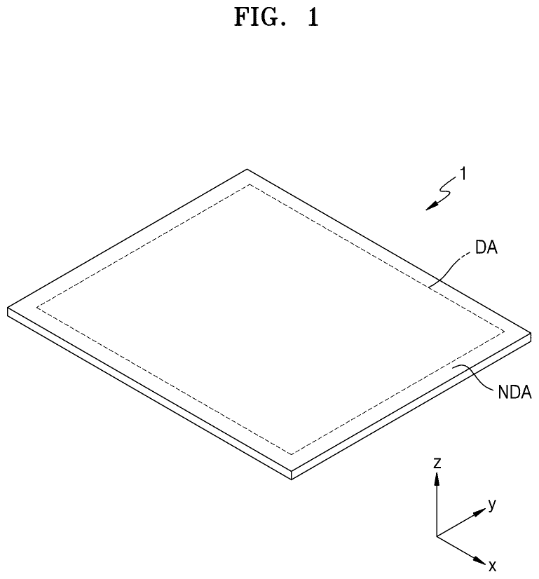

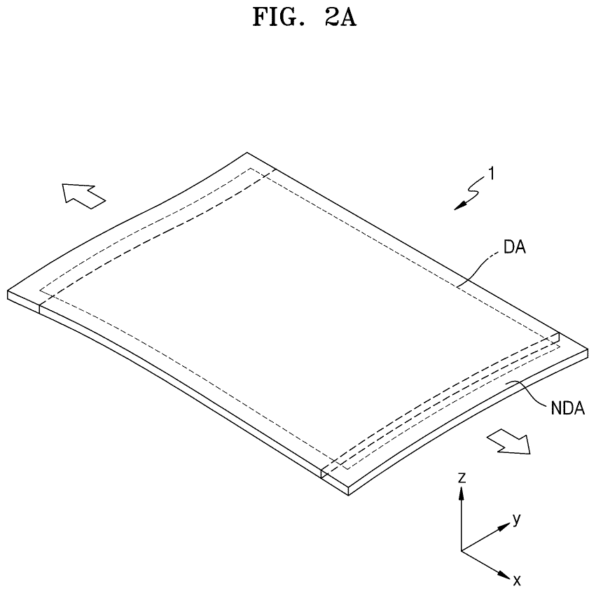

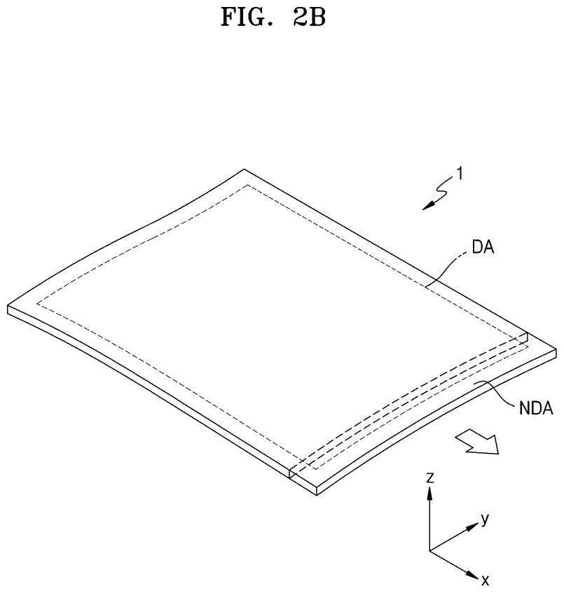

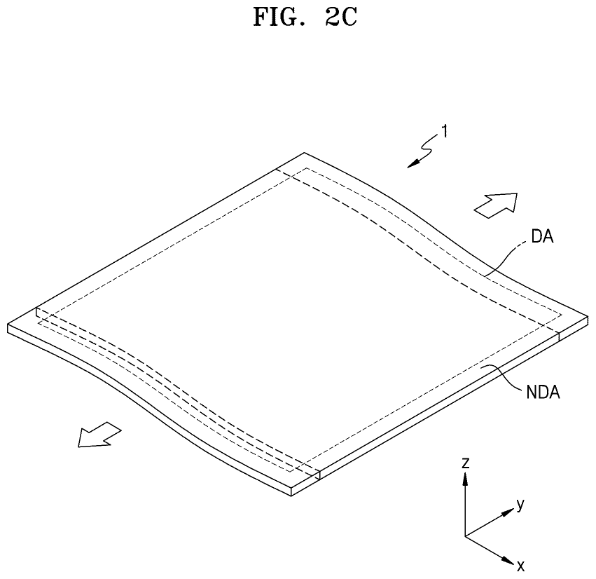

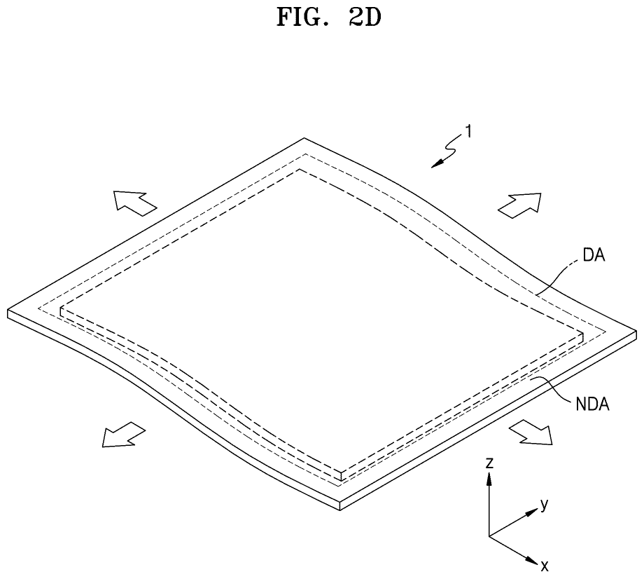

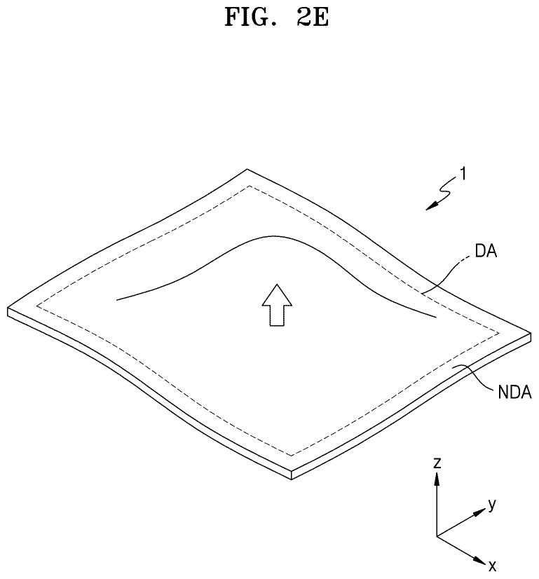

FIG. 1 is a perspective view schematically showing an embodiment of a stretchable display device 1. FIGS. 2A and 2B are perspective views showing the stretchable display device 1 of FIG. 1 stretched in a first direction. FIG. 2C is a perspective view showing the stretchable display device 1 of FIG. 1 stretched in a second direction. FIG. 2D is a perspective view showing the display device of FIG. 1 stretched in the first and second directions. FIG. 2E is a perspective view showing the stretchable display device 1 of FIG. 1 stretched in a third direction.

Referring to FIG. 1, the stretchable display device 1 may include a display area DA and a non-display area NDA. The display area DA may include a plurality of pixels. The stretchable display device 1 may provide a predetermined image by light emitted from the plurality of pixels. The non-display area NDA may be placed outside the display area DA. The non-display area NDA may surround an entirety of the display area DA.

The stretchable display device 1 may be stretched or shrunk in various directions. The stretchable display device 1 may be stretched in a first direction (e.g., x direction and/or −x direction) by an external force applied by an external object or a user. In an embodiment, as shown in FIGS. 2A and 2B, the display area DA and/or the non-display area NDA of the stretchable display device 1 may be stretched in the first direction (e.g., x direction and/or −x direction). In an embodiment, as shown in FIG. 2A, the display area DA and/or the non-display area NDA of the stretchable display device 1 may be stretched in the x direction and −x direction, for example. In an alternative embodiment, as shown in FIG. 2B, the display area DA and/or the non-display area NDA of the stretchable display device 1 may be stretched in the x direction while one side of the stretchable display device 1 is fixed.

The stretchable display device 1 may be stretched in the second direction (e.g., y direction and/or −y direction) by an external force applied by an external object or a user. In an embodiment, as shown in FIG. 2C, the display area DA and/or the non-display area NDA of the stretchable display device 1 may be stretched in the y direction and −y direction. In another embodiment, the display area DA and/or the non-display area NDA of the stretchable display device 1 may be stretched in the y direction or −y direction while one side of the stretchable display device 1 is fixed.

The stretchable display device 1 may be stretched in a plurality of directions, e.g., in the first direction (e.g., x direction and/or −x direction) and the second direction (e.g., y direction and/or −y direction), by an external force applied by an external object or a portion of a person's body. As shown in FIG. 2D, the display area DA and/or the non-display area NDA of the stretchable display device 1 may be stretched in the ±x direction and the ±y direction.

The stretchable display device 1 may be stretched in a third direction (e.g., z direction or −z direction) by an external force applied by an external object or a portion of a person's body. In an embodiment, FIG. 2E shows that a portion of the stretchable display device 1, e.g., a portion of the display area DA protrudes in the z direction. In another embodiment, a portion of the stretchable display device 1, e.g., a portion of the display area DA may protrude in the z direction (or be dented in the −z direction).

Although FIGS. 2A to 2E show that the stretchable display device 1 is stretched in the first direction, the second direction, and/or the third direction, the disclosure is not limited thereto. In another embodiment, the stretchable display device 1 may be deformed into various irregular shapes, such as being bent or twisted along two or more axes.

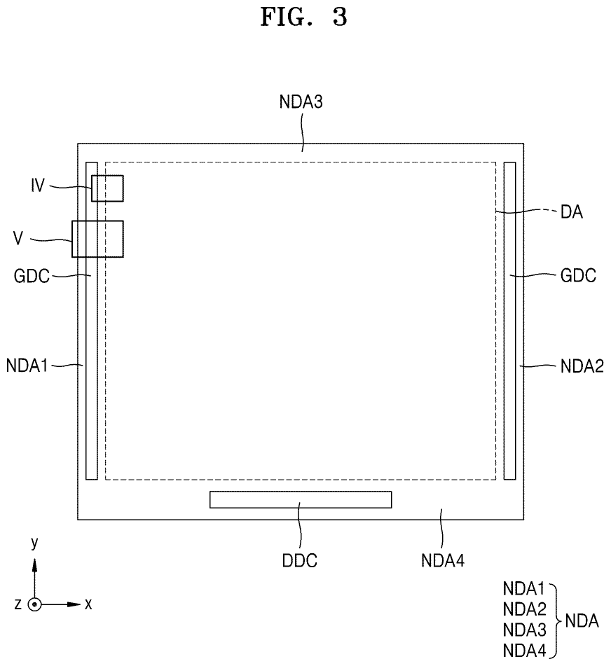

FIG. 3 is a plan view schematically showing an embodiment of a stretchable display device 1.

A plurality of pixels may be arranged in a display area DA of the stretchable display device 1. Each pixel may include sub-pixels that emit light of different colors. Light-emitting elements respectively corresponding to sub-pixels may be arranged in the display area DA. A circuit for providing electrical signals to light-emitting elements arranged in the display area DA and transistors electrically connected to the light-emitting elements may be disposed in a non-display area NDA surrounding the display area DA. A gate driving circuit GDC may be disposed in each of a first non-display area NDA1 and a second non-display area NDA2 on opposite sides of the display area DA. The gate driving circuit GDC may include drivers for providing electrical signals to gate electrodes of the transistors electrically connected to the light-emitting elements. Although FIG. 3 shows that the gate driving circuit GDC is disposed in each of the first non-display area NDA1 and the second non-display area NDA2, the disclosure is not limited thereto. In another embodiment, the gate driving circuit GDC may be disposed in either the first non-display area NDA1 or the second non-display area NDA2.

A data driving circuit DDC may be disposed in a third non-display area NDA3 and/or a fourth non-display area NDA4, which connect the first non-display area NDA1 and the second non-display area NDA2 to each other. In an embodiment, FIG. 3 shows that the data driving circuit DDC is disposed in the fourth non-display area NDA4. In another embodiment, the data driving circuit DDC may be disposed in each of the third non-display area NDA3 and the fourth non-display area NDA4.

Although FIG. 3 shows that the data driving circuit DDC is disposed in the fourth non-display area NDA4 of the stretchable display device 1, the disclosure is not limited thereto. In another embodiment, the stretchable display device 1 may further include a flexible circuit board (not shown) electrically connected through a terminal portion (not shown) disposed in the fourth non-display area NDA4, and the data driving circuit DDC may be disposed on the flexible circuit board.

In some embodiments, the elongation rate of the non-display area NDA may be equal to or less than the elongation rate of the display area DA. In an embodiment, the elongation rate of the non-display area NDA may be different for each area. In an embodiment, the first non-display area NDA1, the second non-display area NDA2, and the third non-display area NDA3 may have substantially the same elongation rate, but the elongation rate of the fourth non-display area NDA4 may be less than the elongation rate of each of the first non-display area NDA1, the second non-display area NDA2, and the third non-display area NDA3, for example.

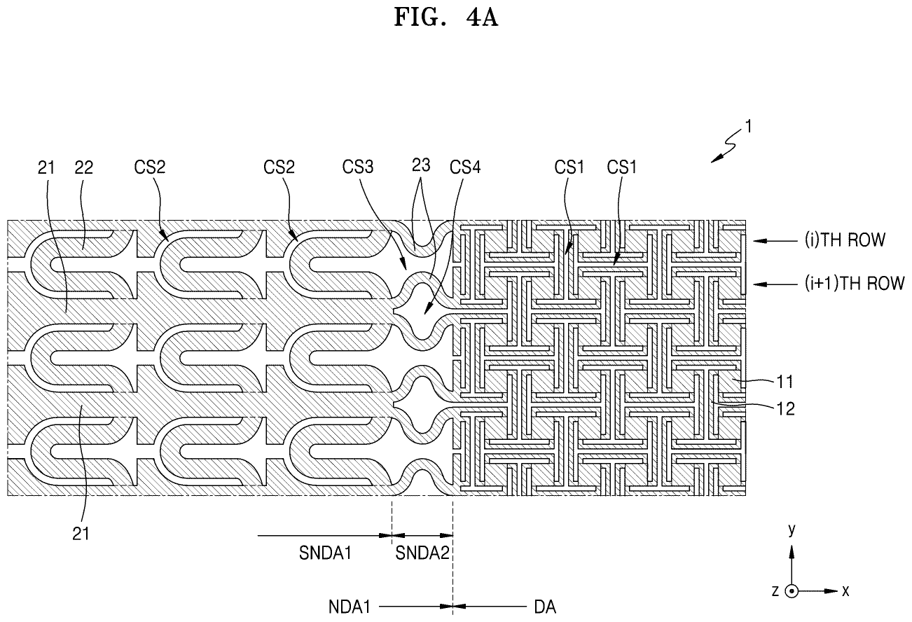

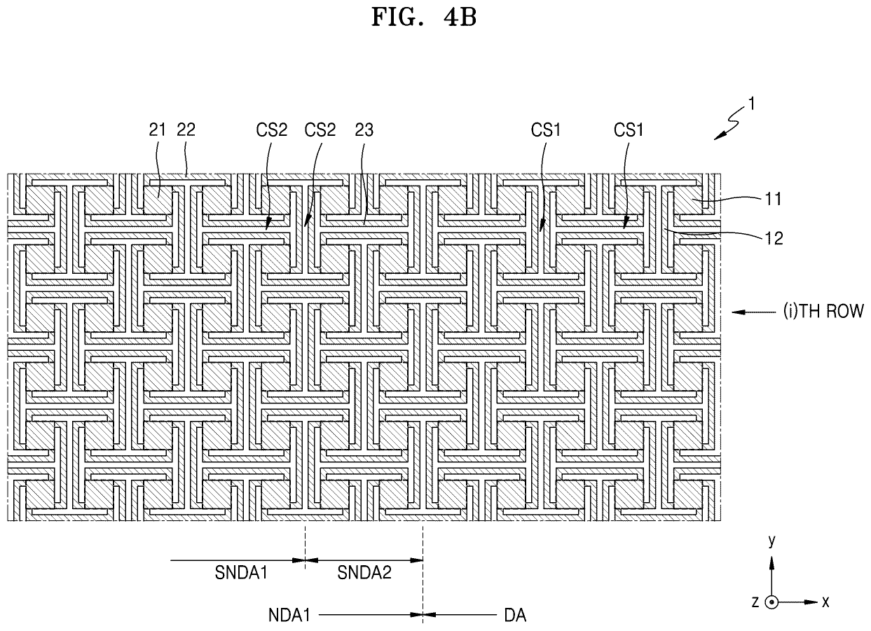

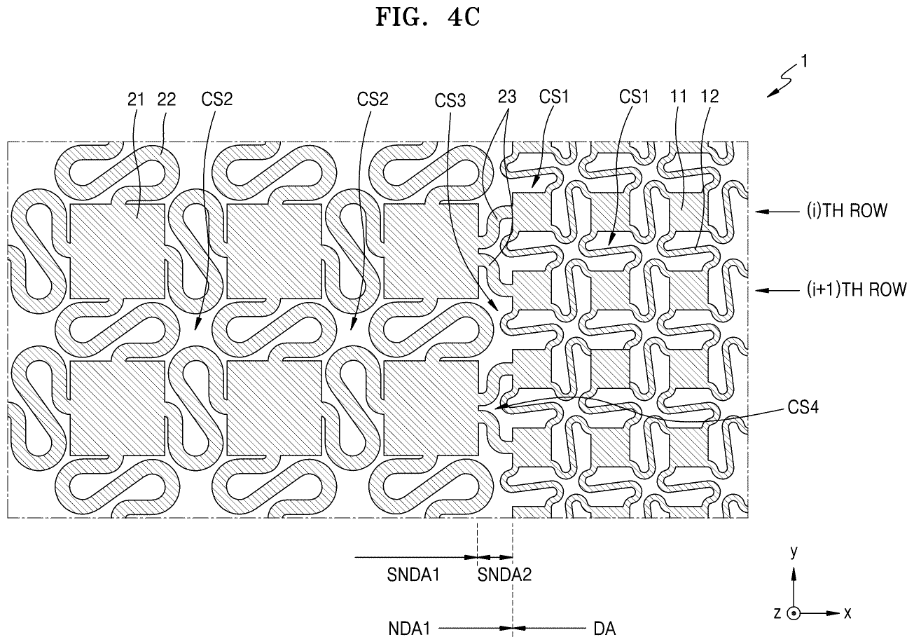

FIG. 4A is an enlarged plan view of an embodiment of an area IV of FIG. 3 as part of a stretchable display device 1.

Referring to FIG. 4A, the stretchable display device 1 may include first island portions 11 spaced apart from each other in a first direction (e.g., x direction or −x direction) and a second direction (e.g., y direction or −y direction) in the display area DA, and first bridge portions 12 connecting adjacent first island portions 11 to each other.

Each of the first island portions 11 may be connected to a plurality of first bridge portions 12. In an embodiment, each of the first island portions 11 may be connected to four first bridge portions 12. Two first bridge portions 12 may be disposed on opposite sides of the first island portion 11 in the first direction (e.g., x direction or −x direction), and the remaining two first bridge portions 12 may be disposed on opposite sides of the first island portion 11 in the second direction (e.g., y direction or −y direction). In an embodiment, the four first bridge portions 12 may be respectively connected to the four sides of the first island portion 11. Each of the four first bridge portions 12 may be adjacent to each corner of the first island portion 11.

The first bridge portions 12 may be spaced apart from each other by a first opening CS1 defined between the first bridge portions 12. In an embodiment, a first opening CS1 having approximately H shape and a first opening CS1 having approximately I shape obtained by rotating the H shape by 90 degrees may be alternately and repeatedly arranged in the first direction (e.g., x direction or −x direction) and the second direction (e.g., y direction or −y direction). Opposite ends of each first bridge portion 12 may be connected to each of the adjacent first island portions 11, and one side of each first bridge portion 12 may be spaced apart from one side of an adjacent first island portion 11 and/or one side of another first bridge portion 12 by the first opening CS1.

The stretchable display device 1 may include second island portions 21 spaced apart from each other in a non-display area, e.g., the first non-display area NDA1 shown in FIG. 4A, and second bridge portions 22 extended to adjacent second island portions 21.

Each of the second island portions 21 may extend in the first direction (e.g., x direction or −x direction). The second island portions 21 may be spaced apart from each other in the second direction (e.g., y direction or −y direction) that crosses the first direction (e.g., x direction or −x direction). Each second island portion 21 may include drivers of the gate driving circuit GDC (refer to FIG. 2) described with reference to FIG. 3.

The second bridge portion 22 may have a serpentine shape. The length of the second bridge portion 22 may be greater than the shortest distance between adjacent second island portions 21 in the second direction (e.g., y direction or −y direction). In an embodiment, the second bridge portion 22 may have an approximately omega (Ω) shape that is convex toward the first direction (e.g., x direction or −x direction). The second bridge portions 22 may be arranged between adjacent second island portions 21 and may be spaced apart from each other.

The second bridge portions 22 between adjacent second island portions 21 may be spaced apart from each other by second openings CS2. Between the adjacent second island portions 21, the second openings CS2 and the second bridge portions 22 may be alternately defined and arranged in the first direction (e.g., x direction or −x direction). The second openings CS2 may have the same shape. Opposite ends of each second bridge portion 22 may be connected to each of the adjacent second island portions 21, and one side of each second bridge portion 22 may be spaced apart from one side of an adjacent second island portion 21 and/or one side of another second bridge portion 22 by the second opening CS2.

One of the second island portions 21 arranged in the first non-display area NDA1 may correspond to a plurality of rows of first island portions 11 arranged in the display area DA1. In an embodiment, one of the second island portions 21 arranged in the first non-display area NDA1 may correspond to first island portions 11 arranged in the (i)th row and first island portions 11 arranged in the (i+1)th row in the display area DA (where i is a positive number greater than 0), for example. Although FIG. 4A shows that one second island portion 21 corresponds to two rows of first island portions 11, but the disclosure is not limited thereto. In another embodiment, one second island portion 21 disposed in the first non-display area NDA1 may correspond to n rows of first island portions 11 arranged in the display area DA1 (where n is a positive number that is equal to or greater than 3).

The non-display area, e.g., the first non-display area NDA1, may include a first sub-non-display area SNDA1 in which the second island portions 21 and the second bridge portions 22, described above, are arranged, and a second sub-non-display area SNDA2 between the first sub-non-display area SNDA1 and the display area DA. Third bridge portions 23 may be in the second sub-non-display area SNDA2 so that the display area DA and the first sub-arranged non-display area SNDA1 are extended to each other. One end of the third bridge portion 23 may be connected to the second island portion 21 and/or the second bridge portion 22, and an opposite end of the third bridge portion 23 may be connected to the first island portion 11 and/or the first bridge portion 12.

The third bridge portion 23 may have a serpentine shape. In an embodiment, the shape of the third bridge portion 23 may be different from the shape of each of the first bridge portion 12 and the second bridge portion 22. In an embodiment, as shown in FIG. 4A, the third bridge portion 23 may have an approximately Ω shape that is convex toward the second direction (e.g., y direction or −y direction). The third bridge portions 23 may have a symmetrical structure, in which one of the adjacent third bridge portions 23 arranged in the second direction (e.g., y direction or −y direction) is convex in the y direction and a remaining one of the adjacent third bridge portions 23 is convex in the −y direction. Between the third bridge portions 23, third openings CS3 and fourth openings CS4 of different shapes may have a repeated structure. The width of the third bridge portion 23 may be different from the width of the first bridge portion 12 and the width of the second bridge portion 22. In an embodiment, the width of the third bridge portion 23 may be greater than the width of the first bridge portion 12 and may be less than the width of the second bridge portion 22.

FIG. 4A shows that the second island portion 21 and the second bridge portion 22 in the non-display area, e.g., the first non-display area NDA1, have different shapes from the first island portion 11 and the first bridge portion 12, respectively, in the display area DA. In another embodiment of the disclosure, the second island portion 21 and the second bridge portion 22 in the non-display area may have the same shape as that of the first island portion 11 and the first bridge portion 12, respectively, in the display area DA.

FIG. 4B is an enlarged plan view of an embodiment of an area IV of FIG. 3 as part of a stretchable display device 1.

Referring to FIG. 4B, the stretchable display device 1 may include first island portions 11 spaced apart from each other in a display area DA and first bridge portions 12 spaced apart from each other by a first opening CS1 and connecting adjacent first island portions 11 to each other. The structure of the display area DA in FIG. 4B may be the same as the structure of the display area DA previously described with reference to FIG. 4A.

The stretchable display device 1 may include second island portions 21 and second bridge portions 22, arranged in a non-display area, e.g., a first non-display area NDA1. In an embodiment, the second island portions 21 and the second bridge portions 22 may have substantially the same shape as that of the first island portions 11 and the first bridge portions 12, respectively.

The second island portions 21 may be spaced apart from each other in a first direction (e.g., x direction or −x direction) and a second direction (e.g., y direction or −y direction) in the non-display area, e.g., the first non-display area NDA1. Each of the second bridge portions 22 may connect adjacent second island portions 21 to each other. The second bridge portions 22 may be spaced apart from each other by a second opening CS2 defined between the second bridge portions 22.

The second opening CS2 may have substantially the same shape as that of the first opening CS1. In an embodiment, a second opening CS2 having approximately H shape and a second opening CS2 having approximately I shape may be alternately and repeatedly arranged in the non-display area, e.g., the first non-display area NDA1, for example. Opposite ends of each second bridge portion 22 may be connected to each of the adjacent second island portions 21, and one side of each second bridge portion 22 may be spaced apart from one side of an adjacent second island portion 21 and/or one side of another second bridge portion 22 by the second opening CS2.

Each second island portion 21 may be connected to four second bridge portions 22. Each second island portion 21 may include drivers of the gate driving circuit GDC (refer to FIG. 2) described with reference to FIG. 3.

Second island portions 21 in one row arranged in the first non-display area NDA1 may correspond to first island portions 11 in one row arranged in the display area DA1. In an embodiment, second island portions 21 arranged in the (i)th row in the first direction (e.g., x direction or −x direction) in the first non-display area NDA1 may correspond to first island portions 11 arranged in the same row, e.g., the (i)th row, in the display area DA (where i is a positive number greater than 0), for example.

The stretchable display device 1 may include third bridge portions 23 arranged in the second sub-non-display area SNDA2 for connecting the display area DA to the first sub-non-display area SNDA1. A non-display area, e.g., the first non-display area NDA1, may include a first sub-non-display area SNDA1 in which the second island portions 21 and the second bridge portions 22 are arranged, and a second sub-non-display area SNDA2 including third bridge portions 23 and disposed between the first sub-non-display area SNDA1 and the display area DA. The third bridge portion 23 may be substantially the same as the first bridge portion 12 and the second bridge portion 22. In an embodiment, the width of the third bridge portion 23 may be the same as the width of the first bridge portion 12 and the width of the second bridge portion 22, for example.

FIG. 4C is an enlarged plan view of an embodiment of an area IV of FIG. 3 as part of a stretchable display device.

Referring to FIG. 4C, the stretchable display device 1 may include first island portions 11 spaced apart from each other in a first direction (e.g., x direction or −x direction) and a second direction (e.g., y direction or −y direction) in the display area DA, and first bridge portions 12 extended to adjacent first island portions 11 to each other.

The first bridge portions 12 may be arranged to be spaced apart from each other by the first opening CS1 defined between the first bridge portions 12. The first bridge portion 12 may have a serpentine shape. In an embodiment, as shown in FIG. 4C, the first bridge portion 12 may have the shape of approximately ‘alphabet S’, for example.

Each of the first island portions 11 may be extended to a plurality of first bridge portions 12. In an embodiment, each of the first island portions 11 may be extended to four first bridge portions 12, for example. Two first bridge portions 12 may be disposed on opposite sides of the first island portion 11 in the first direction (e.g., x direction or −x direction), and the remaining two first bridge portions 12 may be disposed on opposite sides of the first island portion 11 in the second direction (e.g., y direction or −y direction). The four first bridge portions 12 may be respectively extended to the four sides of the first island portion 11. Each of the four first bridge portions 12 may be adjacent to each corner of the first island portion 11.

The stretchable display device 1 may include second island portions 21 spaced apart from each other in a first direction (e.g., x direction or −x direction) and a second direction (e.g., y direction or −y direction) in a non-display area, e.g., in the first non-display area NDA1 shown in FIG. 4C, and second bridge portions 22 extended to adjacent second island portions 21.

The second bridge portions 22 may be arranged to be spaced apart from each other by the second opening CS2 defined between the second bridge portions 22. The second bridge portion 22 may have a serpentine shape. In an embodiment, as shown in FIG. 4C, the second bridge portion 22 may have the shape of approximately ‘alphabet S’, for example. The size and/or width of the second bridge portion 22 may be different from the size and/or width of the first bridge portion 12. In an embodiment, the size and/or width of the second bridge portion 22 may be greater than the size and/or width of the first bridge portion 12, for example. The radius of curvature of a round portion of the second bridge portion 22 may be different from the radius of curvature of a round portion of the first bridge portion 12. In an embodiment, the radius of curvature of the round portion of the second bridge portion 22 may be greater than the radius of curvature of the round portion of the first bridge portion 12.

Each of the second island portions 21 may be extended to a plurality of second bridge portions 22. Each of the second island portions 21 may be extended to four second bridge portions 22. Two second bridge portions 22 may be disposed on opposite sides of the second island portion 21 in the first direction (e.g., x direction or −x direction), and the remaining two second bridge portions 22 may be disposed on opposite sides of the second island portion 21 in the second direction (e.g., y direction or −y direction). In an embodiment, the four second bridge portions 22 may be respectively extended to the four sides of the second island portion 21. Each second bridge portion 22 may be extended to a central portion of each side of the second island portion 21.

Second island portions 21 in one row arranged in the first non-display area NDA1 may correspond to first island portions 11 in a plurality of rows arranged in the display area DA1. In an embodiment, the second island portions 21 in one row arranged in the first non-display area NDA1 may correspond to first island portions 11 arranged in the (i)th row of the display area DA and first island portions 11 arranged in the (i+1)th row (where i is a positive number greater than 0). In another embodiment, one row of second island portions 21 may correspond to n rows of first island portions 11 (where n is a positive number that is equal to or greater than 3), for example.

The non-display area, e.g., the first non-display area NDA1, may include a first sub-non-display area SNDA1 in which the second island portions 21 and the second bridge portions 22, described above, are arranged, and a second sub-non-display area SNDA2 between the first sub-non-display area SNDA1 and the display area DA. Third bridge portions 23 may be arranged in the second sub-non-display area SNDA2 so that the display area DA and the first sub-non-display area SNDA1 are extended to each other. One end of the third bridge portion 23 may be extended to the second island portion 21 and an opposite end of the third bridge portion 23 may be extended to the first island portion 11. In an embodiment, one end of the third bridge portion 23 may be extended to a central portion of one side of the second island portion 21, and an opposite end of the third bridge portion 23 may be extended to a central portion of one side of the first island portion 11, for example.

The third bridge portion 23 may have a serpentine shape. In an embodiment, the shape of the third bridge portion 23 may be different from the shape of each of the first bridge portion 12 and the second bridge portion 22. The width of the third bridge portion 23 may be different from the width of the first bridge portion 12 and the width of the second bridge portion 22. The width of the third bridge portion 23 may be greater than the width of the first bridge portion 12 and may be less than the width of the second bridge portion 22. Third openings CS3 and fourth openings CS4 of different shapes may be alternately defined between the third bridge portions 23 in the second direction (e.g., y direction or −y direction).

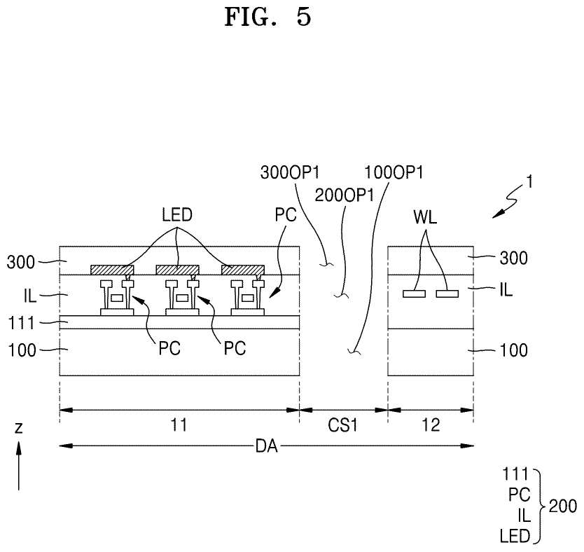

FIG. 5 is a cross-sectional view schematically showing an embodiment of a first island portion 11 and a first bridge portion 12 arranged in a display area DA of a stretchable display device 1.

Referring to FIG. 5, the first island portion 11 and the first bridge portion 12 arranged in the display area DA may be spaced apart from each other with a first opening CS1 therebetween. The first island portion 11 may include light-emitting elements LED and a circuit (e.g., pixel driving circuit portion PC for driving the light-emitting elements LED electrically connected thereto, and the first bridge portion 12 may include a wiring line WL electrically connected to pixel driving circuit portions PC arranged in each of the adjacent first island portions 11.

In the first island portion 11, a buffer layer 111 including an inorganic insulating material may be disposed on a substrate 100, and a pixel driving circuit portion PC may be disposed on the buffer layer 111. An insulating layer IL including an inorganic insulating material and/or an organic insulating material may be disposed between the pixel driving circuit portion PC and the light-emitting element LED. The light-emitting element LED may be disposed on the insulating layer IL and may be electrically connected to a corresponding pixel driving circuit portion PC. Light-emitting elements LED may emit light of different colors or the same color. In an embodiment, each of the light-emitting elements LED may emit red light, green light, or blue light. In some embodiments, the light-emitting elements LED may emit white light. In another embodiment, each of the light-emitting elements LED may emit red light, green light, blue light, or white light.

The substrate 100 may include a polymer resin, such as polyethersulfone, polyarylate, polyether imide, polyethylene naphthalate, polyethylene terephthalate, polyphenylene sulfide, polyimide, polycarbonate, cellulose triacetate, or cellulose acetate propionate. In an embodiment, the substrate 100 may include a single layer including the aforementioned resin. In another embodiment, the substrate 100 may have a multi-layered structure including a base layer including the aforementioned polymer resin and a barrier layer including an inorganic insulating material. The substrate 100 including a polymer resin may be flexible, rollable, or bendable.

In an embodiment, FIG. 5 shows that three pixel driving circuit portions PC are arranged in each of the first island portions 11 and three light-emitting elements LED are connected to each of the pixel driving circuit portions PC. However, the disclosure is not limited thereto. In another embodiment, the number of pixel driving circuit portions PC and light-emitting elements LED arranged in the first island portion 11 may be one, two, or four or more.

An encapsulation layer 300 may be disposed on the light-emitting elements LED and may protect the light-emitting elements LED from external force and/or moisture penetration. The encapsulation layer 300 may include an inorganic encapsulation layer and/or an organic encapsulation layer. In some embodiments, the encapsulation layer 300 may have a structure in which an inorganic encapsulation layer including an inorganic insulating material, an organic encapsulation layer including an organic insulating material, and an inorganic encapsulation layer including an inorganic insulating material are stacked. In another embodiment, the encapsulation layer 300 may include an organic material, such as resin. In some embodiments, the encapsulation layer 300 may include urethane epoxy acrylate. The encapsulation layer 300 may include a photosensitive material, such as photoresist.

In the first bridge portion 12, an insulating layer IL including an organic insulating material may be disposed on the substrate 100. When the stretchable display device 1 is stretched, unlike the first island portion 11, there may not be a layer including an inorganic insulating material, which is prone to cracks, in the first bridge portion 12, which is relatively deformed.

In an embodiment, the substrate 100 corresponding to the first bridge portion 12 may have the same stacked structure as that of the substrate 100 corresponding to the first island portion 11. In an embodiment, the substrate 100 corresponding to the first bridge portion 12 and the substrate 100 corresponding to the first island portion 11 may be polymer resin layers formed together in the same process. In another embodiment, the substrate 100 corresponding to the first bridge portion 12 may have a different stack structure from the substrate 100 corresponding to the first island portion 11. In some embodiments, the substrate 100 corresponding to the first bridge portion 12 may have a multi-layered structure including a base layer including a polymer resin and a barrier layer including an inorganic insulating material, and the substrate 100 corresponding to the first island portion 11 may have a structure of a polymer resin layer without a layer including an inorganic insulating material.

As described above, wiring lines WL of the first bridge portion 12 may be signal lines (e.g., gate lines and data lines) for providing electrical signals to transistors included in the pixel driving circuit portion PC of the first island portion 11, or voltage lines (e.g., driving voltage lines and initialization voltage lines) for providing voltages. The encapsulation layer 300 may also be disposed in the first bridge portion 12. In another embodiment, the encapsulation layer 300 may not be present in the first bridge portion 12.

Referring to FIGS. 4A to 4C and FIG. 5, the substrate 100 corresponding to the first island portion 11 and the substrate 100 corresponding to the first bridge portion 12 may be connected to or extended to each other. In other words, the plan views shown in FIGS. 4A to 4C may be substantially the same as the plan view of the substrate 100 in FIG. 5. In other words, the substrate 100 may include an area corresponding to the first island portion 11 and an area corresponding to the first bridge portion 12, and may define an opening 100OP1 having the same shape as that of the first opening CS1.

Similarly, the encapsulation layer 300 corresponding to the first island portion 11 and the encapsulation layer 300 corresponding to the first bridge portion 12 may be connected to or extended to each other. In an embodiment, the plan views shown in FIGS. 4A to 4C may be substantially the same as the plan view of the encapsulation layer 300, for example. In other words, the encapsulation layer 300 may include an area corresponding to the first island portion 11 and an area corresponding to the first bridge portion 12, and may define an opening 300OP1 having the same shape as that of the first opening CS1.

A circuit-light-emitting element layer 200 between the substrate 100 and the encapsulation layer 300 may include a buffer layer 111, a pixel driving circuit portion PC, a wiring line WL, an insulating layer IL, and a light-emitting element LED. Similar to the substrate 100, the plan view shown in FIGS. 4A to 4C may be substantially the same as the plan view of the circuit-light-emitting element layer 200. In other words, the circuit-light-emitting element layer 200 may define an opening 200OP1 having the same shape as that of the first opening CS1.

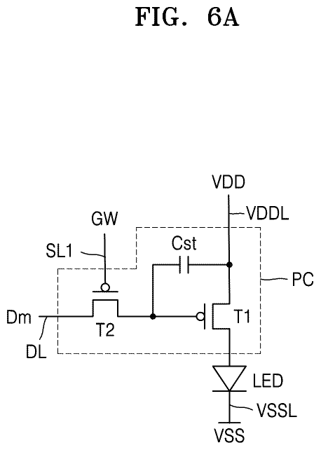

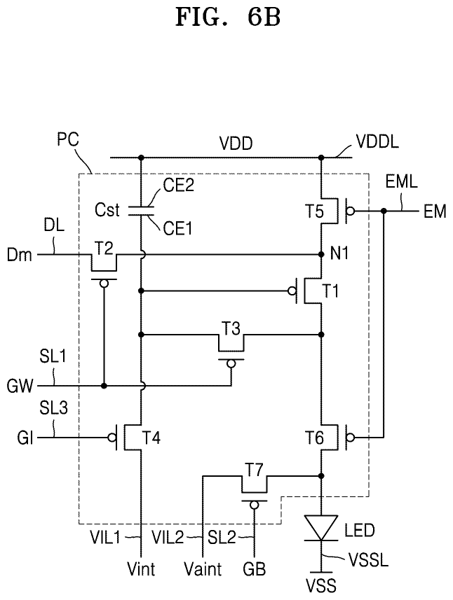

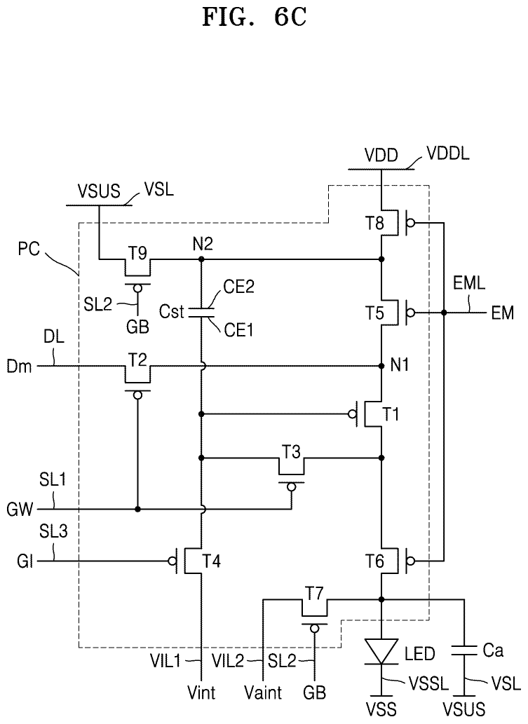

FIGS. 6A to 6C are equivalent circuit diagrams of an embodiment of a sub-pixel of the stretchable display device 1.

Referring to FIG. 6A, a light-emitting element LED corresponding to the sub-pixel may be electrically connected to a pixel driving circuit portion PC, and the pixel driving circuit portion PC may include a first transistor T1, a second transistor T2, and a storage capacitor Cst. The pixel driving circuit portion PC may be electrically connected to a signal line and a voltage line. The signal line may include a gate line such as a first scan line SL1, and a data line DL, and the voltage line may include a first voltage line VDDL.

The second transistor T2 may be electrically connected to the first scan line SL1 and the data line DL. The first scan line SL1 may provide a first scan signal GW to a gate electrode of the second transistor T2. The second transistor T2 may transmit a data signal Dm input from the data line DL to the first transistor T1 according to the first scan signal GW input from the first scan line SL1.

The storage capacitor Cst may be electrically connected to the second transistor T2 and the first voltage line VDDL and may store a voltage corresponding to the difference between a voltage received from the second transistor T2 and a first power voltage VDD supplied by the first voltage line VDDL.

The first transistor T1 may be a driving transistor and may control a driving current flowing through the light-emitting element LED. The first transistor T1 may be connected to the first voltage line VDDL and the storage capacitor Cst. The first transistor T1 may control a driving current flowing from the first voltage line VDDL to the light-emitting element LED in response to a voltage value stored in the storage capacitor Cst. The light-emitting element LED may emit light having a predetermined brightness by the driving current. A first electrode of the light-emitting element LED may be electrically connected to the first transistor T1, and a second electrode of the light-emitting element LED may be electrically connected to a second voltage line VSSL that supplies a second power voltage VSS.

FIG. 6A shows that the pixel driving circuit portion PC includes two transistors and one storage capacitor. However, in another embodiment, the pixel driving circuit portion PC may include three or more transistors.

Referring to FIG. 6B, a pixel driving circuit portion PC may include a first transistor T1, a second transistor T2, a third transistor T3, a fourth transistor T4, a fifth transistor T5, a sixth transistor T6, a seventh transistor T7, and a storage capacitor Cst.

The pixel driving circuit portion PC is electrically connected to signal lines and voltage lines. The signal lines may include gate lines, such as a first scan line SL1, a second scan line SL2, and a third scan line SL3, and an emission control line EML, and a data line DL. The voltage lines may include first and second initialization voltage lines VIL1 and VIL2 and a first voltage line VDDL.

The first voltage line VDDL may transmit a first power voltage VDD to the first transistor T1. The first initialization voltage line VIL1 may transmit a first initialization voltage Vint, which initializes the first transistor T1, to the pixel driving circuit portion PC. The second initialization voltage line VIL2 may transmit a second initialization voltage Vaint, which initializes a first electrode of a light-emitting element LED, to the pixel driving circuit portion PC.

The first transistor T1 may be electrically connected to the first voltage line VDDL via the fifth transistor T5 and may be electrically connected to the light-emitting element LED via the sixth transistor T6. The first transistor T1 may function as a driving transistor and may receive a data signal Dm according to a switching operation of the second transistor T2 and supply a driving current to the light-emitting element LED.

The second transistor T2 may be a data writing transistor and may be electrically connected to the first scan line SL1 and the data line DL. The second transistor T2 may be electrically connected to the first voltage line VDDL via the fifth transistor T5. The second transistor T2 may be turned on according to a first scan signal GW received through the first scan line SL1 and transmit the data signal Dm transmitted to the data line DL to a first node N1. That is, the second transistor T2 may perform a switching operation.

The third transistor T3 may be electrically connected to the first scan line SL1 and to the light-emitting element LED via the sixth transistor T6. The third transistor T3 may be turned on according to a first scan signal GW received through the first scan line SL1 and diode-connect the first transistor T1.

The fourth transistor T4 may be a first initialization transistor and may be electrically connected to the third scan line SL3 and the first initialization voltage line VIL1. The fourth transistor T4 may be turned on according to a third scan signal GI received through the third scan line SL3 and transmit the first initialization voltage Vint from the first initialization voltage line VIL1 to a gate electrode of the first transistor TI to initialize the voltage of the gate electrode of the first transistor T1. The third scan signal GI may correspond to the first scan signal of another pixel driving circuit portion disposed in the previous row of a corresponding pixel driving circuit portion PC.

The fifth transistor T5 may be an operation control transistor, and the sixth transistor T6 may be an emission control transistor. The fifth transistor T5 and the sixth transistor T6 may be electrically connected to the emission control line EML and may be simultaneously turned on according to an emission control signal EM received through the emission control line EML and form a current path so that a driving current may flow from the first voltage line VDDL to the light-emitting element LED.

The seventh transistor T7 may be a second initialization transistor and may be electrically connected to the second scan line SL2, the second initialization voltage line VIL2, and the sixth transistor T6. The seventh transistor T7 may be turned on according to a second scan signal GB received through the second scan line SL2 and transmit the second initialization voltage Vaint from the second initialization voltage line VIL2 to the first electrode of the light-emitting element LED to initialize the first electrode of the light-emitting element LED.

The storage capacitor Cst may include a first electrode CE1 and a second electrode CE2. The first electrode CE1 may be electrically connected to the gate electrode of the first transistor T1, and the second electrode CE2 may be electrically connected to the first voltage line VDDL. The storage capacitor Cst may store and maintains a voltage corresponding to the voltage difference between the first voltage line VDDL and the gate electrode of the first transistor T1, thereby maintain the voltage applied to the gate electrode of the first transistor T1.

Referring to FIG. 6C, a pixel driving circuit portion PC may include a first transistor T1, a second transistor T2, a third transistor T3, a fourth transistor T4, a fifth transistor T5, a sixth transistor T6, a seventh transistor T7, an eighth transistor T8, a ninth transistor T9, a storage capacitor Cst, and an auxiliary capacitor Ca.

The pixel driving circuit portion PC may be electrically connected to signal lines and voltage lines. The signal lines may include gate lines, such as a first scan line SL1, a second scan line SL2, and a third scan line SL3, and an emission control line EML, and a data line DL. The voltage lines may include first and second initialization voltage lines VIL1 and VIL2, a maintenance voltage line VSL, and a first voltage line VDDL.

The first voltage line VDDL may transmit a first power voltage VDD to the first transistor T1. The first initialization voltage line VIL1 may transmit a first initialization voltage Vint, which initializes the first transistor T1, to the pixel driving circuit portion PC. The second initialization voltage line VIL2 may transmit a second initialization voltage Vaint, which initializes a first electrode of a light-emitting element LED, to the pixel driving circuit portion PC. The maintenance voltage line VSL may provide a maintenance voltage VSUS to a second node N2, e.g., a second electrode CE2 of the storage capacitor Cst, during an initialization period and a data writing period.

The first transistor T1 may be electrically connected to the first voltage line VDDL via the fifth transistor T5 and the eighth transistor T8 and may be electrically connected to the light-emitting element LED via the sixth transistor T6. The first transistor T1 may function as a driving transistor and may receive a data signal Dm according to a switching operation of the second transistor T2 and supply a driving current to the light-emitting element LED.

The second transistor T2 may be electrically connected to the first scan line SL1 and the data line DL and may be electrically connected to the first voltage line VDDL via the fifth transistor T5 and the eighth transistor T8. The second transistor T2 may be turned on according to a first scan signal GW received through the first scan line SL1 and transmit the data signal Dm transmitted to the data line DL to a first node N1. That is, the second transistor T2 may perform a switching operation.

The third transistor T3 may be electrically connected to the first scan line SL1 and to the light-emitting element LED via the sixth transistor T6. The third transistor T3 may be turned on according to a first scan signal GW received through the first scan line SL1 and diode-connect the first transistor T1, thereby compensating for the threshold voltage of the first transistor T1.

The fourth transistor T4 may be electrically connected to the third scan line SL3 and the first initialization voltage line VIL1 and may be turned on according to a third scan signal GI received through the third scan line SL3 and transmit the first initialization voltage Vint from the first initialization voltage line VIL1 to a gate electrode of the first transistor T1 to initialize the voltage of the gate electrode of the first transistor T1. The third scan signal GI may correspond to the first scan signal of another pixel driving circuit portion disposed in the previous row of a corresponding pixel driving circuit portion PC.

The fifth transistor T5, the sixth transistor T6, and the eighth transistor T8 may be electrically connected to the emission control line EML and may be simultaneously turned on according to an emission control signal EM received through the emission control line EML and form a current path so that a driving current may flow from the first voltage line VDDL to the light-emitting element LED.

The seventh transistor T7 may be a second initialization transistor and may be electrically connected to the second scan line SL2, the second initialization voltage line VIL2, and the sixth transistor T6. The seventh transistor T7 may be turned on according to a second scan signal GB received through the second scan line SL2 and transmit the second initialization voltage Vaint from the second initialization voltage line VIL2 to the first electrode of the light-emitting element LED to initialize the first electrode of the light-emitting element LED.

The ninth transistor T9 may be electrically connected to the second scan line SL2, the second electrode CE2 of the storage capacitor Cst, and the maintenance voltage line VSL. The ninth transistor T9 may be turned on according to a second scan signal GB received through the second scan line SL2 and transmit a maintenance voltage VSUS to a second node N2, e.g., the second electrode CE2 of the storage capacitor Cst, during an initialization period and a data writing period.

The eighth transistor T8 and the ninth transistor T9 may each be electrically connected to the second node N2, e.g., the second electrode CE2 of the storage capacitor Cst. In some embodiments, in the initialization period and the data writing period, the eighth transistor T8 may be turned off and the ninth transistor T9 may be turned on, and in an emission period, the eighth transistor T8 may be turned on and the ninth transistor T9 may be turned off. Because the maintenance voltage VSUS is transmitted to the second node N2 in the initialization period and the data writing period, the uniformity (e.g., long range uniformity (“LRU”)) of luminance of the stretchable display device according to the voltage drop of the first voltage line VDDL may be improved.

The storage capacitor Cst may include a first electrode CE1 and a second electrode CE2. The first electrode CE1 may be electrically connected to the gate electrode of the first transistor T1, and the second electrode CE2 may be electrically connected to the eighth transistor T8 and the ninth transistor T9.

The auxiliary capacitor Ca may be electrically connected to the sixth transistor T6, the maintenance voltage line VSL, and the first electrode of the light-emitting element LED. The auxiliary capacitor Ca may store and maintain a voltage corresponding to the voltage difference between the first electrode of the light-emitting element LED and the maintenance voltage line VSL while the seventh transistor T7 and the ninth transistor T9 are turned on, and thus may prevent black luminance from increasing when the sixth transistor T6 is turned off.

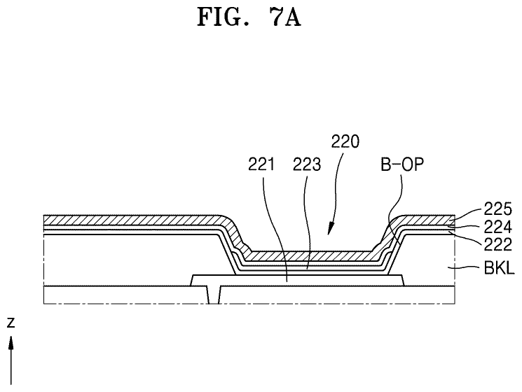

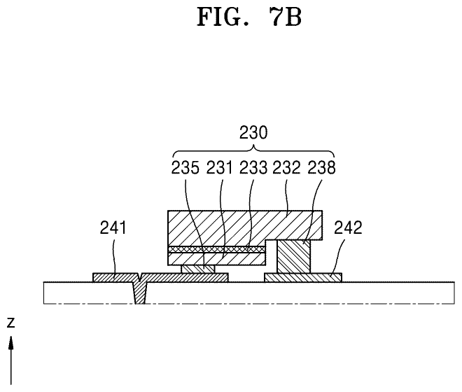

FIG. 7A is a cross-sectional view schematically showing an embodiment of a light-emitting element of a stretchable display device.

Referring to FIG. 7A, a light-emitting element in an embodiment may include an organic light-emitting diode 220 including an organic material. The organic light-emitting diode 220 may include a first electrode 221 disposed on an insulating layer, a second electrode 225 facing the first electrode 221, and an emission layer 223 disposed between the first electrode 221 and the second electrode 225. A first functional layer 222 may be disposed between the first electrode 221 and the emission layer 223, and a second functional layer 224 may be disposed between the emission layer 223 and the second electrode 225.

The edge of the first electrode 221 may be covered with a bank layer BKL including an insulating material. An opening B-OP overlapping a center portion of the first electrode 221 may be defined in the bank layer BKL.

The first electrode 221 may include a conductive oxide, such as indium tin oxide (“ITO”), indium zinc oxide (“IZO”), zinc oxide (ZnO), indium oxide (In₂O₃), indium gallium oxide (“IGO”), or aluminum zinc oxide (“AZO”). In another embodiment, the first electrode 221 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or compounds thereof. In another embodiment, the first electrode 221 may further include a layer including or consisting of ITO, IZO, ZnO, or In₂O₃, above/below the reflective layer described above.

The emission layer 223 may include a polymeric or low-molecular-weight organic material that emits a predetermined color of light. The first functional layer 222 may include a hole transport layer (“HTL”) and/or a hole injection layer (“HIL”). The second functional layer 224 may include an electron transport layer (“ETL”) and/or an electron injection layer (“EIL”).

The second electrode 225 may include a conductive material with a relatively low work function. In an embodiment, the second electrode 225 may include a (semi-)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), any alloys thereof, or the like, for example. In an alternative embodiment, the second electrode 225 may further include a layer including ITO, IZO, ZnO, AZO, or In₂O₃ on the (semi-)transparent layer including the materials described above.

FIG. 7B is a cross-sectional view schematically showing an embodiment of a light-emitting element of a stretchable display device.

Referring to FIG. 7B, a light-emitting element in an embodiment may include an inorganic light-emitting diode 230 including an inorganic material. The inorganic light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the inorganic light-emitting diode 230 may be electrically connected to a first electrode pad 241 and a second electrode pad 242, respectively, disposed in the same layer.

In some embodiments, the first semiconductor layer 231 may include a p-type semiconductor layer. The p-type semiconductor layer may include a semiconductor material having a composition formula of InxAlyGa1-x-yN (0≤x≤1, 0≤y≤1, and 0≤x+y≤1), such as GaN, AlN, AlGaN, InGaN, InN, InAlGaN, or AlInN, and may be doped with a p-type dopant, such as Mg, Zn, Ca, Sr, or Ba.

The second semiconductor layer 232 may include an n-type semiconductor layer, for example. The n-type semiconductor layer may include a semiconductor material having a composition formula of InxAlyGal-x-yN (0≤x≤1, 0≤y≤1, and 0≤x+y≤1), such as GaN, AlN, AlGaN, InGaN, InN, InAlGaN, or AlInN, and may be doped with an n-type dopant, such as Si, Ge, and Sn.

The intermediate layer 233 is a region where electrons and holes recombine. As the electrons and the holes recombine, the intermediate layer 233 may transition to a lower energy level and may generate light with a wavelength corresponding thereto. In an embodiment, the intermediate layer 233 may include a semiconductor material having a composition formula of InxAlyGal-x-yN (0≤x≤1, 0≤y≤1, and 0≤x+y≤1), and may be formed to have a single quantum well structure or a multi quantum well (“MQW”) structure, for example. In addition, the intermediate layer 233 may include a quantum wire structure or a quantum dot structure.

Although FIG. 7B illustrates that the first semiconductor layer 231 includes a p-type semiconductor layer and the second semiconductor layer 232 includes an n-type semiconductor layer, the disclosure is not limited thereto. In another embodiment, the first semiconductor layer 231 may include an n-type semiconductor layer, and the second semiconductor layer 232 may include a p-type semiconductor layer.

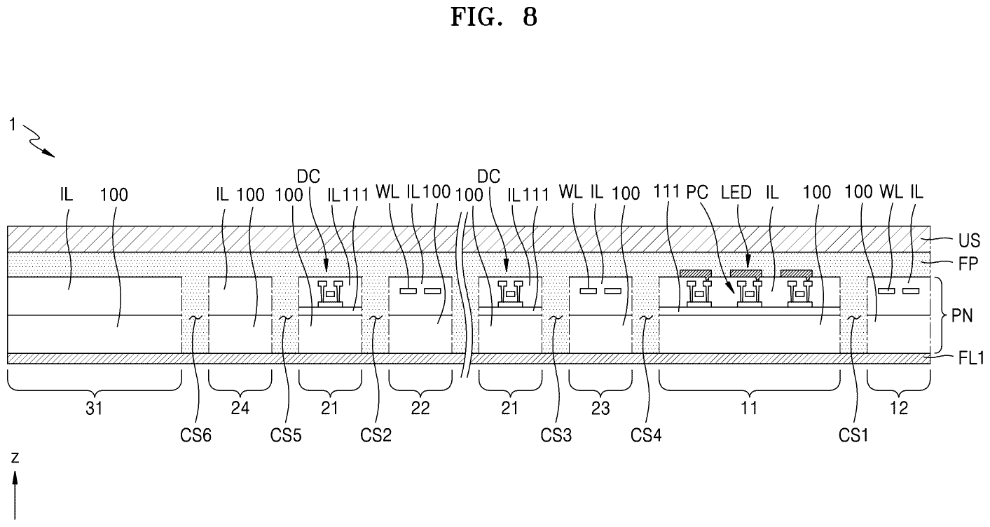

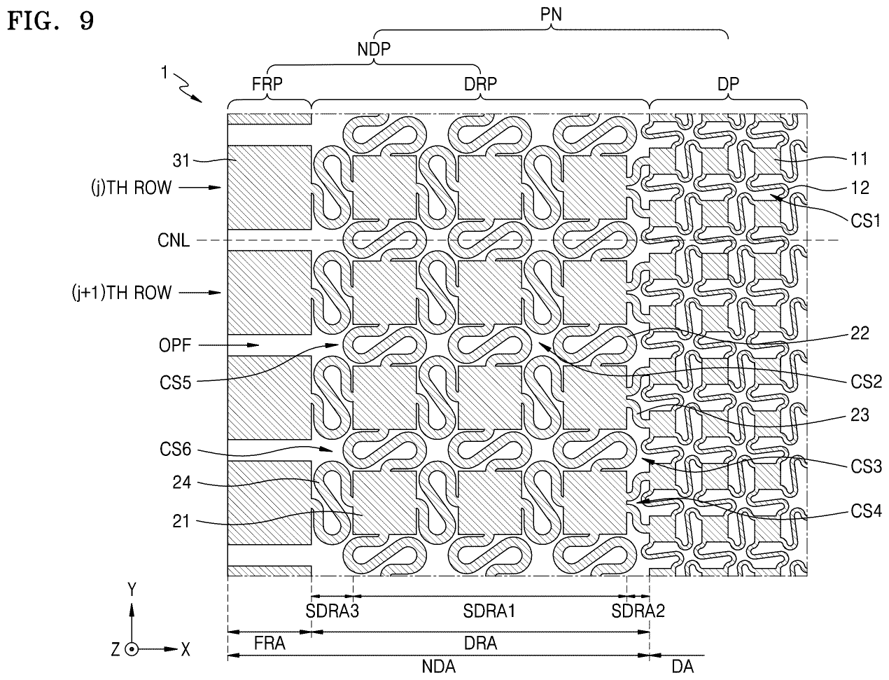

FIG. 8 is a schematic cross-sectional view of an embodiment of a portion of a stretchable display device 1, and FIG. 9 is a schematic plan view of an embodiment of a portion of a stretchable display device 1. Specifically, FIG. 9 is an enlarged plan view of an area V of FIG. 3.

In FIGS. 8 and 9, the same reference numerals as those in FIGS. 4A to 4C and 5 refer to the same members as those in FIGS. 4A to 4C and 5, and thus, redundant descriptions thereof are omitted.

In addition, although FIG. 9 illustrates the embodiment shown in FIG. 4C, the planar shape of the stretchable display device 1 is not limited thereto, and the embodiments shown in FIGS. 4A and 4B may also be applied.

Referring to FIGS. 8 and 9, the stretchable display device 1 may include a first film FL1, a display panel PN, an upper substrate US, and a filling portion FP.

The first film FL1 may include a flexible material that may be stretched. In an embodiment, the first film FL1 may include at least one of polydimethylsiloxane (“PDMS”) and polyurethane (“PU”), for example. The first film FL1 may be disposed on the entirety of the area of the stretchable display device 1.

The display panel PN may be disposed on the first film FL1. The display panel PN may include a flexible material that may be stretched. The display panel PN may display an image by a plurality of pixels. The display panel PN may include a substrate 100, a buffer layer 111, an insulating layer IL, a pixel driving circuit portion PC, a panel driving circuit portion DC, and a wiring line WL. A detailed description of the display panel PN will be described later.

The upper substrate US may be disposed on the display panel PN. The upper substrate US may include a flexible material that may be stretched. In an embodiment, the upper substrate US may include a polymer resin, such as polyethersulfone, polyarylate, polyether imide, polyethylene naphthalate, polyethylene terephthalate, polyphenylene sulfide, polyimide, polycarbonate, cellulose triacetate, or cellulose acetate propionate, for example. In an embodiment, the upper substrate US may include a single layer including the aforementioned resin. In another embodiment, the upper substrate US may have a multi-layered structure including a base layer including the aforementioned polymer resin and a barrier layer including an inorganic insulating material. The upper substrate US including a polymer resin may be flexible, rollable, or bendable.

The filling portion FP may be disposed between the first film FL1 and the upper substrate US. The filling portion FP may contact the display panel PN. At least a portion of the filling portion FP may be accommodated in an opening of the display panel PN. The filling portion FP may include an optically clear resin (“OCA”) material. In an embodiment, the filling portion FP may include an elastomer material, for example.

The display panel PN may include a display portion DP disposed in a display area DA and a non-display portion NDP disposed in a non-display area NDA. The non-display portion NDP may include a driver portion DRP disposed in a driver area DRA and a frame portion FRP disposed in a frame area FRA.

The display portion DP, the driver portion DRP, and the frame portion FRP may be sequentially arranged in a first direction (e.g., −x direction). The display portion DP may be disposed at the center of the stretchable display device 1, the frame portion FRP may be disposed on the outside of the stretchable display device 1, and the driver portion DRP may be disposed between the display portion DP and the frame portion FRP.

The display portion DP may include a plurality of first island portions 11 and a plurality of first bridge portions 12. The plurality of first island portions 11 may be arranged to be spaced apart from each other. Each of the plurality of first island portions 11 may include a light-emitting element LED and a circuit for driving the light-emitting element LED electrically connected thereto, e.g., a pixel driving circuit portion PC.

In the first island portion 11, a buffer layer 111 including an inorganic insulating material may be disposed on a substrate 100, and the pixel driving circuit portion PC may be disposed on the buffer layer 111. An insulating layer IL including an inorganic insulating material and/or an organic insulating material may be disposed between the pixel driving circuit portion PC and the light-emitting element LED. The light-emitting element LED may be disposed on the insulating layer IL and may be electrically connected to a corresponding pixel driving circuit portion PC.

In the first bridge portion 12, an insulating layer IL including an organic insulating material may be disposed on the substrate 100. In addition, the first bridge portion 12 may include a wiring line WL electrically connected to the pixel driving circuit portion PC disposed in each of the adjacent first island portions 11. A first opening CS1 may be defined adjacent to the first island portion 11, and the adjacent first island portions 11 may be spaced apart from each other with the first opening CS1 therebetween.

The driver area DRA may include a first sub-driver area SDRA1, a second sub-driver area SDRA2, and a third sub-driver area SDRA3. The second sub-driver area SDRA2, the first sub-driver area SDRA1, and the third sub-driver area SDRA3 may be sequentially arranged in the first direction (e.g., −x direction). That is, the second sub-driver area SDRA2 may be between the display area DA and the first sub-driver area SDRA1, and the third sub-driver area SDRA3 may be between the first sub-driver area SDRA1 and the frame area FRA.

The driver portion DRP may include a plurality of second island portions 21 and a plurality of second bridge portions 22 arranged in the first sub-driver area SDRA1, a plurality of third bridge portions 23 arranged in the second sub-driver area SDRA2, and a plurality of fourth bridge portions 24 arranged in the third sub-driver area SDRA3.

The plurality of second island portions 21 may be arranged to be spaced apart from each other. A driver that provides an electrical signal to the light-emitting element LED may be disposed in each of the plurality of second island portions 21. Each of the plurality of second island portions 21 may include a circuit (e.g., a panel driving circuit portion DC) for providing an electrical signal to the gate electrode of each of the transistors electrically connected to the light-emitting elements LED.

In the second island portion 21, a buffer layer 111 including an inorganic insulating material may be disposed on the substrate 100, and the panel driving circuit portion DC may be disposed on the buffer layer 111. An insulating layer IL including an inorganic insulating material and/or an organic insulating material may be disposed on the panel driving circuit portion DC.

In the second bridge portion 22, an insulating layer IL including an organic insulating material may be disposed on the substrate 100. In addition, the second bridge portion 22 may include a wiring line WL electrically connected to the panel driving circuit portion DC disposed in each of the adjacent second island portions 21. A second opening CS2 may be defined adjacent to the second bridge portion 22, and the adjacent second island portion 21 may be spaced apart from each other with the second opening CS2 therebetween.

In the third bridge portion 23, an insulating layer IL including an organic insulating material may be disposed on the substrate 100. In addition, the third bridge portion 23 may include a wiring line WL electrically connected to the pixel driving circuit portion PC disposed in an adjacent first island portion 11 and the panel driving circuit portion DC disposed in an adjacent second island portion 21. A third opening CS3 and a fourth opening CS4 may be defined adjacent to the third bridge portion 23, and a first island portion 11 and a second island portion 21 adjacent to each other may be spaced apart from each other with the third opening CS3 and the fourth opening CS4 therebetween.

In the fourth bridge portion 24, an insulating layer IL including an organic insulating material may be disposed on the substrate 100. The fourth bridge portion 24 may be extended to an adjacent second island portion 21 and a third island portion 31, which will be described later. A fifth opening CS5 and a sixth opening CS6 may be defined adjacent to the fourth bridge portion 24, and a second island portion 21 and a third island portion 31 adjacent to each other may be spaced apart from each other with the fifth opening CS5 and the sixth opening CS6 therebetween.

The frame portion FRP may include a plurality of third island portions 31. The plurality of third island portions 31 may be arranged to be spaced apart from each other. In an embodiment, the plurality of third island portions 31 may be arranged to be spaced apart in a second direction (e.g., y direction and/or −y direction). In the third island portion 31, an insulating layer IL including an organic insulating material may be disposed on the substrate 100, for example. A frame opening OPF may be defined between adjacent third island portions 31. That is, the adjacent third island portions 31 may be spaced apart from each other with the frame opening OPF therebetween.

Any one of the plurality of second island portions 21 may be extended to any one of the plurality of third island portions 31. In an embodiment, each of the plurality of third island portions 31 may be extended to one second island portion 21, for example. One second island portion 21 may be extended to one fourth bridge portion 24, and one fourth bridge portion 24 may be extended to one third island portion 31. That is, one second island portion 21 and one third island portion 31 may be extended to each other by each of the plurality of fourth bridge portions 24 arranged in the third sub-driver area SDRA3.

The plurality of fourth bridge portions 24 may be spaced apart from each other by the fifth opening CS5 and the sixth opening CS6. The fifth opening CS5 may be defined between one fourth bridge portion 24 and another fourth bridge portion 24, and the sixth opening CS6 may be defined between one fourth bridge portion 24 and another fourth bridge portion 24. That is, the fifth opening CS5 and the sixth opening CS6 may be alternately defined in the second direction (e.g., y direction and/or −y direction). In a plan view, the shape of the fifth opening CS5 and the shape of the sixth opening CS6 may be the same.

One second island portion 21 may correspond to one third island portion 31. In an embodiment, one second island portion 21 disposed in the (j)th row may correspond to one third island portion 31 arranged in the (j)th row (where j is a positive number greater than 0), for example. In addition, one second island portion 21 disposed in the (j+1)th row may correspond to one third island portion 31 disposed in the (j+1)th row (where j is a positive number greater than 0).

In this structure, two adjacent second island portions 21 may be symmetrical to each other with respect to a center line CNL between two adjacent third island portions 31. That is, the center line CNL between two adjacent third island portions 31 may pass through the center of the second bridge portion 22. In addition, with respect to the center line CNL between two adjacent third island portions 31, two adjacent first island portions 11 may be symmetrical to each other. That is, the center line CNL between two adjacent third island portions 31 may pass through the center of the first bridge portion 12.

The third island portion 31 may be larger in size than each of the first island portion 11 and the second island portion 21. The length of the third island portion 31 in the first direction (e.g., x direction and/or −x direction) may be greater than the length of each of the first island portion 11 and the second island portion 21 in the first direction (e.g., x direction and/or −x direction). The length of the third island portion 31 in the second direction (e.g., y direction and/or −y direction) may be greater than the length of each of the first island portion 11 and the second island portion 21 in the second direction (e.g., y direction and/or −y direction). In this structure, the stretchable display device 1 may maintain its shape without being flabby due to the frame portion FRP.

The elongation rates of the display portion DP, the driver portion DRP, and the frame portion FRP may be different from each other.

First, comparing the driver portion DRP with the display portion DP, the number of first bridge portions 12 per unit area may be greater than the number of second bridge portions 22 per unit. Therefore, the elongation rate of the display portion DP may be greater than the elongation rate of the driver portion DRP.

Specifically, per unit area, the number of first bridge portions 12 extended to adjacent first island portions 11 spaced apart in the first direction (e.g., x direction and/or −x direction) may be greater than the number of second bridge portions 22 extended to adjacent second island portions 21 spaced apart in the first direction (e.g., x direction and/or −x direction). Accordingly, the elongation rate of the display portion DP in the first direction (e.g., x direction and/or −x direction) may be greater than the elongation rate of the driver portion DRP in the first direction (e.g., x direction and/or −x direction).

In addition, per unit area, the number of first bridge portions 12 extended to adjacent first island portions 11 spaced apart in the second direction (e.g., y direction and/or −y direction) may be greater than the number of second bridge portions 22 extended to adjacent second island portions 21 spaced apart in the second direction (e.g., y direction and/or −y direction). Accordingly, the elongation rate of the display portion DP in the second direction (e.g., y direction and/or −y direction) may be greater than the elongation rate of the driver portion DRP in the second direction (e.g., y direction and/or −y direction).

Comparing the driver portion DRP with the frame portion FRP, the plurality of third island portions 31 may be arranged in a row in the second direction (e.g., y direction and/or −y direction) and may not be arranged to be spaced apart from each other in the first direction (e.g., x direction and/or −x direction). Accordingly, the length of the driver portion DRP in the first direction (e.g., x direction and/or −x direction) may be greater than the length of the frame portion FRP in the first direction (e.g., x direction and/or −x direction).

In addition, the plurality of third island portions 31 may be spaced apart from each other in the second direction (e.g., y direction and/or −y direction). Unlike the plurality of second island portions 21, the plurality of third island portions 31 may not be extended by a separate bridge portion. Accordingly, the elongation rate of the frame portion FRP in the second direction (e.g., y direction and/or −y direction) may be greater than the elongation rate of the driver portion DRP in the second direction (e.g., y direction and/or −y direction).

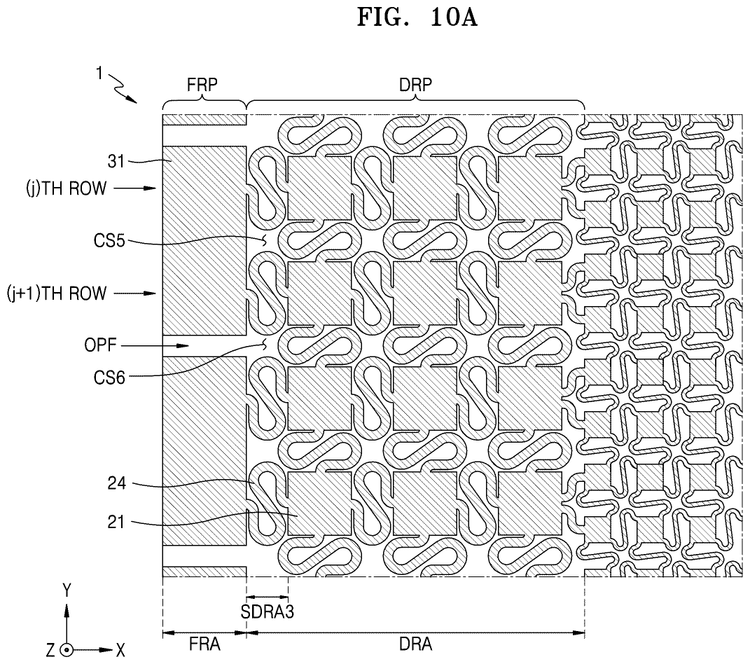

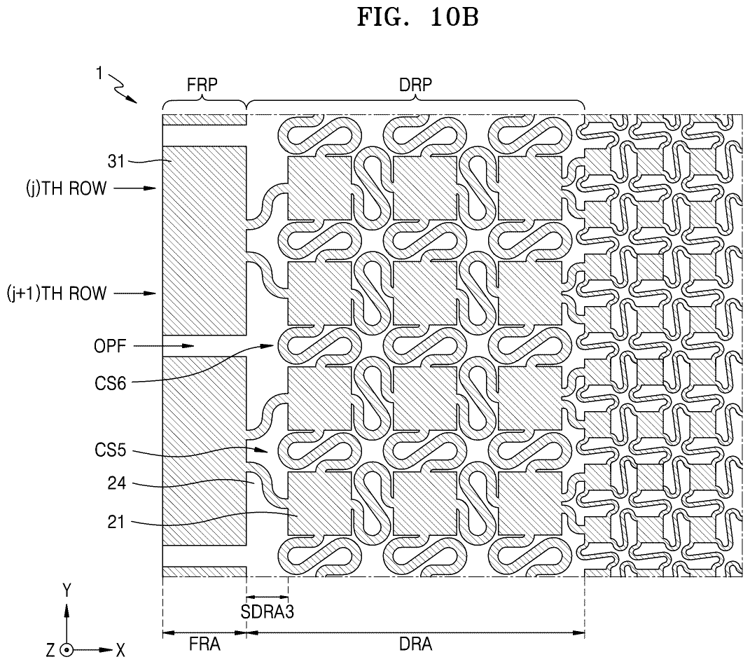

FIGS. 10A and 10B are schematic plan views of an embodiment of a portion of a stretchable display device 1. Specifically, FIGS. 10A and 10B are enlarged plan views of the area V of FIG. 3.

In FIGS. 10A and 10B, the same reference numerals as those in FIGS. 8 and 9 refer to the same members as those in FIGS. 8 and 9, and thus, redundant descriptions thereof are omitted.

Referring to FIGS. 10A and 10B, at least two of the plurality of second island portions 21 may be extended to any one of the plurality of third island portions 31.

The number of second island portions 21 extended to one third island portion 31 may be plural. One third island portion 31 of the frame portion FRP may correspond to a plurality of second island portions 21 of the driver portion DRP. The fourth bridge portion 24 disposed in the third sub-driver area DRA of the driver area DRA may extend to the second island portion 21 and the third island unit 31. The number of fourth bridge portions 24 may correspond to the number of second island portions 21.

In an embodiment, two fourth bridge portions 24 may be extended to one third island portion 31 disposed in the frame area FRA, and one second island portion 21 may be extended to each of the two fourth bridge portions 24. That is, one third island portion 31, two fourth bridge portions 24, and two second island portions 21 arranged in the (j)th row and (j+1) row may be extended to each other, for example. However, this is only an example, and the number of fourth bridge portions 24 and second island portions 21 extended to one third island portion 31 is not limited thereto.

As shown in FIG. 10A, the shape of the fifth opening CS5 and the shape of the sixth opening CS6 may be the same in a plan view. In this case, the fifth opening CS5 may be an opening defined between the fourth bridge portions 24 extended to one third island portion 31. In addition, the sixth opening CS6 may be an opening defined between two adjacent fourth bridge portions 24 respectively extended to two adjacent third island portions 31. That is, the sixth opening CS6 may be an opening that communicates with the frame opening OPF. The fifth opening CS5 and the sixth opening CS6 may be alternately defined in the second direction (e.g., y direction and/or −y direction), and the shape of the fifth opening CS5 and the shape of the sixth opening CS6 may be the same. The shapes of the plurality of fourth bridge portions 24 may be the same. In addition, the distance between two adjacent fourth bridge portions 24 may be constant.

As shown in FIG. 10B, the shape of the fifth opening CS5 and the shape of the sixth opening CS6 may be different from each other in a plan view. The distance between the plurality of fourth bridge portions 24 extended to one third island portion 31 may be narrowed in the first direction (e.g., −x direction). Accordingly, the size of the fifth opening CS5 may be less than the size of the sixth opening CS6. The plurality of fourth bridge portions 24 extended to the one third island portion 31 may be symmetrical. However, the shapes of the plurality of fourth bridge portions 24, the fifth opening CS5, and the sixth opening CS6 shown in FIG. 10B are only examples and are not limited thereto.

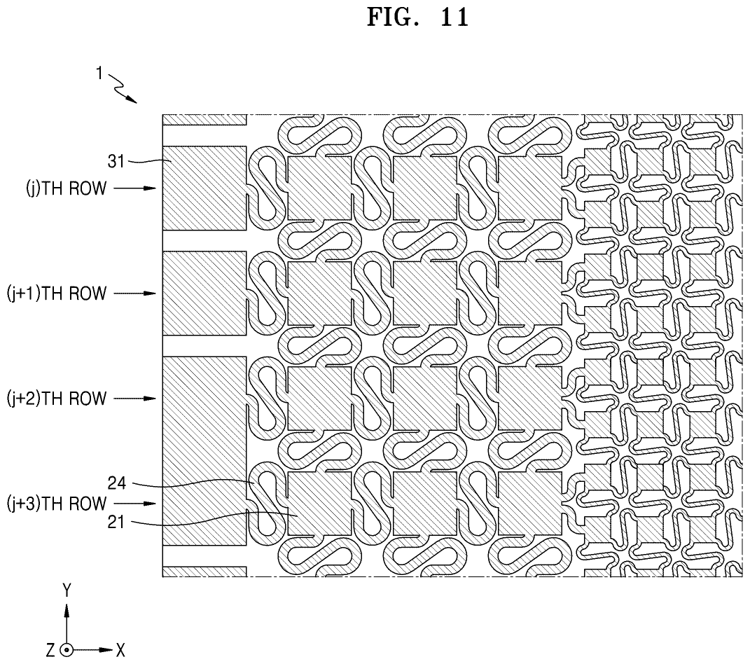

FIG. 11 is a schematic plan view of an embodiment of a portion of a stretchable display device 1. Specifically, FIG. 11 is an enlarged plan view of the area V of FIG. 3.

In FIG. 11, the same reference numerals as those in FIGS. 8 and 9 refer to the same members as those in FIGS. 8 and 9, and thus, redundant descriptions thereof are omitted.

Referring to FIG. 11, at least two of the plurality of second island portions 21 may be extended to any one of the plurality of third island portions 31, and different numbers of second island portions 21 may be extended to at least two of the plurality of third island portions 31. In addition, the shapes of at least two of the plurality of third island portions 31 may be different from each other.

In an embodiment, as shown in FIG. 11, the shape of the third island portion 31 disposed in the (j)th row and the shape of the third island portion 31 disposed in the (j+1)th row may be the same, for example. One fourth bridge portion 24 may be extended to each of the third island portions 31 arranged in the (j)th row and the (j+1)th row, and one second island portion 21 may be extended to one fourth bridge portion 24.

The third island portion 31 disposed in the (j+2)th row and the (j+3)th row may be integrally provided as a single body. Accordingly, the planar size of one third island portion 31 disposed in the (j+2)th row and the (j+3)th row may be greater than the planar size of each of the third island portions 31 arranged in the (j)th row and the (j+1)th row. In addition, a plurality of second island portions 21 may be extended to the one third island portion 31 disposed in the (j+2)th row and the (j+3)th row. In an embodiment, two fourth bridge portions 24 may be extended to the one third island portion 31 disposed in the (j+2)th row and the (j+3)th row, and one second island portion 21 may be extended to each of the two fourth bridge portions 24, for example.

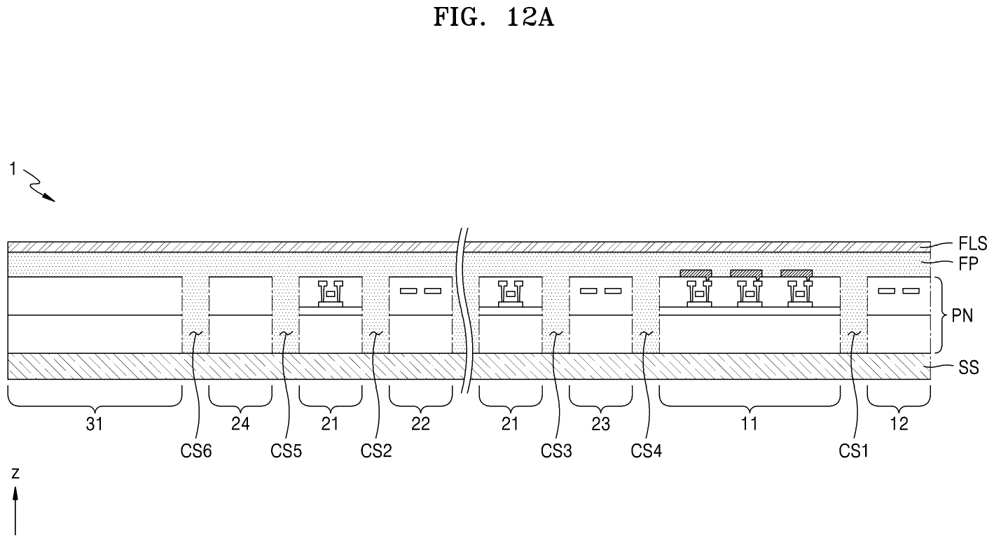

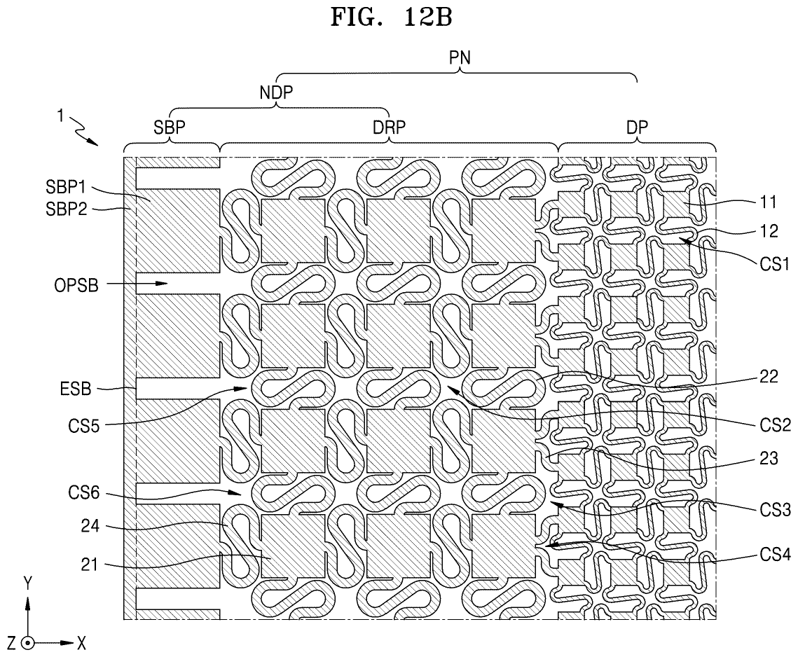

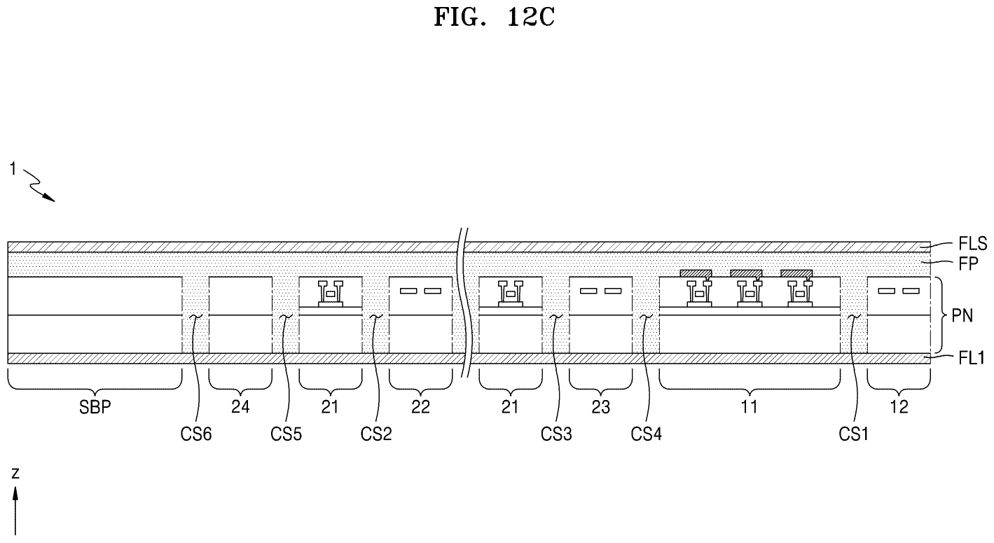

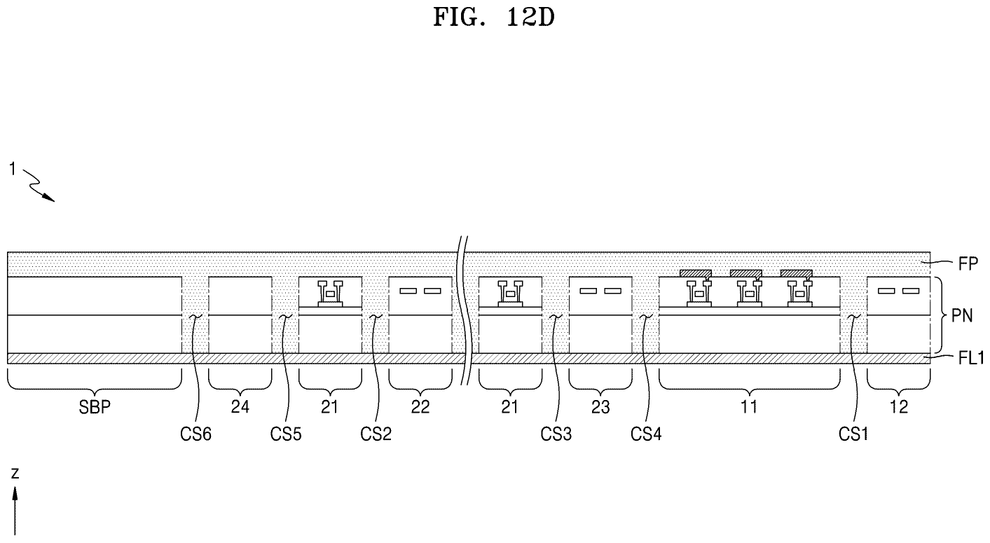

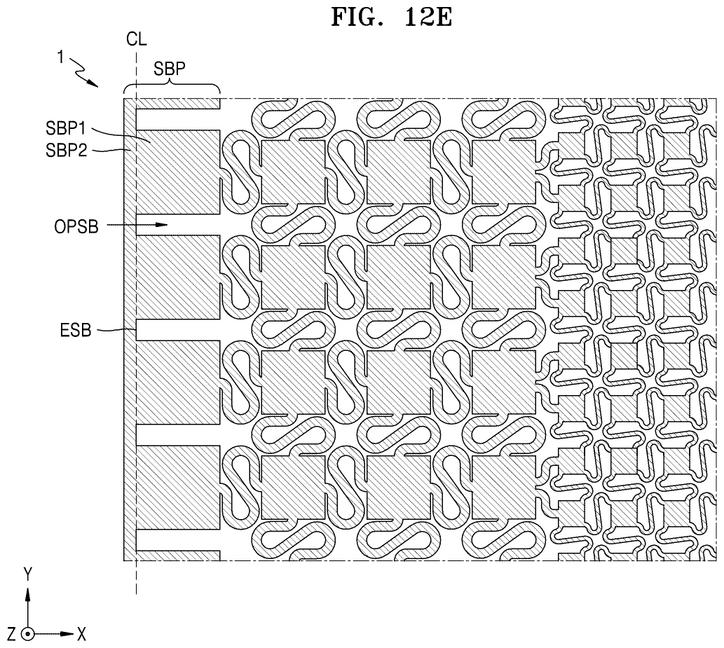

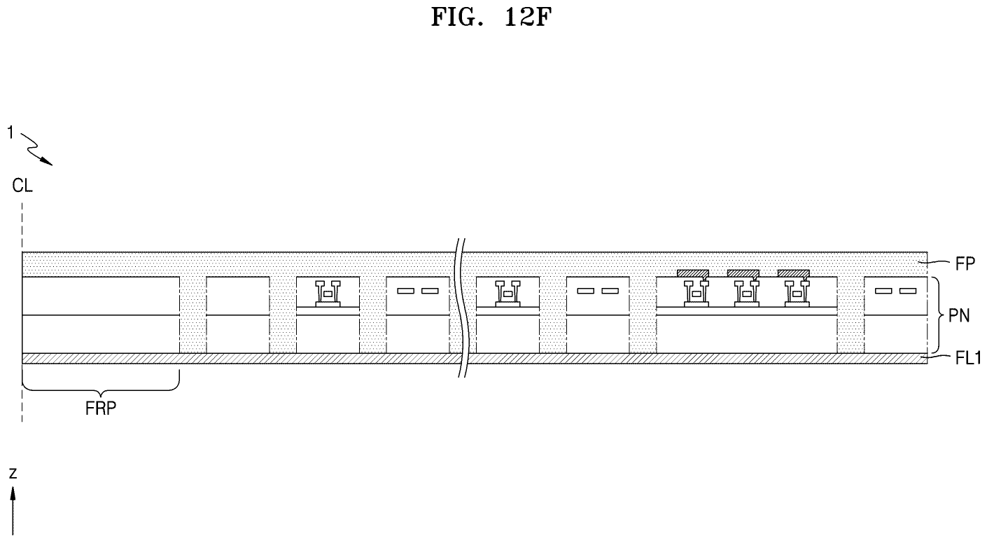

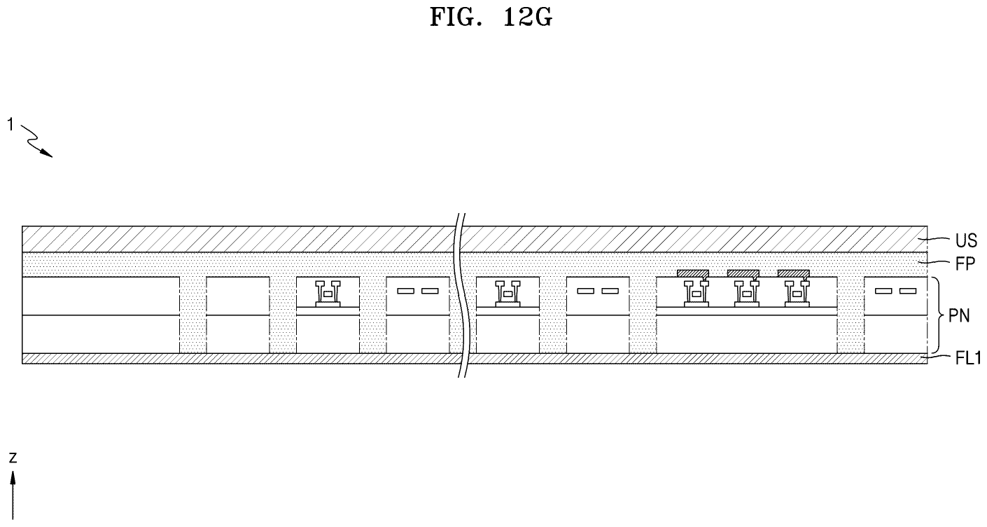

FIG. 12A is a schematic cross-sectional view of an embodiment of a portion of a stretchable display device 1, FIG. 12B is a schematic plan view of an embodiment of a portion of a stretchable display device 1, and FIGS. 12C and 12D are schematic cross-sectional views of a portion of a stretchable display device 1. FIG. 12E is a schematic plan view of an embodiment of a portion of a stretchable display device 1, and FIGS. 12F and 12G are schematic cross-sectional views of an embodiment of a portion of a stretchable display device 1.

In FIGS. 12A to 12F, the same reference numerals as those in FIGS. 8 and 9 refer to the same members as those in FIGS. 8 and 9, and thus, redundant descriptions thereof are omitted.

Referring to FIGS. 12A to 12F, a method of manufacturing a stretchable display device 1 may be seen.

First, referring to FIGS. 12A and 12B, the method of manufacturing the stretchable display device 1 may include disposing a display panel PN on a support substrate SS, and disposing a support film FLS on the display panel PN.

The support substrate SS may include glass having a sufficient thickness. The support substrate SS may have sufficient hardness to reduce bending or deformation of the display panel PN including a flexible material during the manufacturing process.

The display panel PN may include a display portion DP and a non-display portion NDP sequentially arranged in a first direction (e.g., −x direction), and the non-display portion NDP may include a driver portion DRP and an outer portion SBP sequentially arranged in the first direction (e.g., −x direction). That is, the display panel PN may include the display portion DP, the driver portion DRP, and the outer portion SBP that are sequentially arranged in the first direction (e.g., −x direction). Because the display portion DP and the driver portion DRP have been described above with reference to FIGS. 8 and 9, detailed descriptions thereof are omitted.

The outer portion SBP may include a plurality of sawtooth portions SBP1 and a connecting portion SBP2. The plurality of sawtooth portions SBP1 may be arranged to be spaced apart from each other in a second direction (e.g., y direction and/or −y direction). A sawtooth opening OPSB may be defined between the plurality of sawtooth portions SBP1. That is, the sawtooth opening OPSB may define a space between the plurality of sawtooth portions SBP1. The sawtooth opening OPSB may communicate with the fifth opening CS5 and the sixth opening CS6. That is, two adjacent sawtooth portions SBP1 may be arranged to be spaced apart with one sawtooth opening OPSB therebetween. The connecting portion SBP2 may be disposed from the plurality of sawtooth portions SBP1 in the first direction (e.g., −x direction) so that the plurality of sawtooth portions SBP1 is extended to each other. The connecting portion SBP2 may be disposed outside the plurality of sawtooth portions SBP1 and connect the plurality of sawtooth portions SBP1 to each other. The connecting portion SBP2 and the plurality of sawtooth portions SBP1 may be provided as one body.

The method of manufacturing the stretchable display device 1 may further include disposing a filling portion FP on the display panel PN before disposing the support film FLS on the display panel PN. In this case, the disposing of the support film FLS on the display panel PN may be disposing the support film FLS on the filling portion FP disposed on the display panel PN.

Referring to FIG. 12C, the method of manufacturing the stretchable display device 1 may include removing the support substrate SS (refer to FIG. 12A) from the display panel PN, and disposing the display panel PN on a first film FL1.

The support film FLS may have a higher modulus than that of the first film FL1. In an embodiment, the support film FLS may include a polyethylene terephthalate (“PET”) material, for example. Accordingly, in the removing of the support substrate SS (refer to FIG. 12A) from the display panel PN, the support film FLS may reduce bending or deformation of the display panel PN.

When the support substrate SS (refer to FIG. 12A) is removed, the first film FL1 may be attached to a lower portion of the display panel PN. In this process, the support substrate SS (refer to FIG. 12A) may be replaced with the first film FL1. Accordingly, the display panel PN may be disposed on the first film FL1.

Referring to FIGS. 12D and 12E, the method of manufacturing the stretchable display device 1 may include removing the support film FLS (refer to FIG. 12C) from the display panel PN, and cutting the outer portion SBP along a cutting line CL.

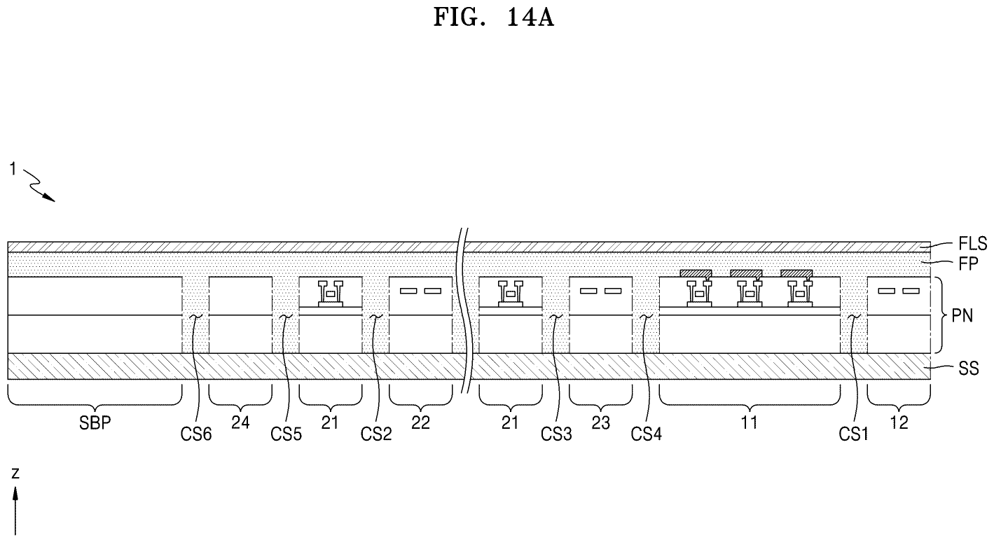

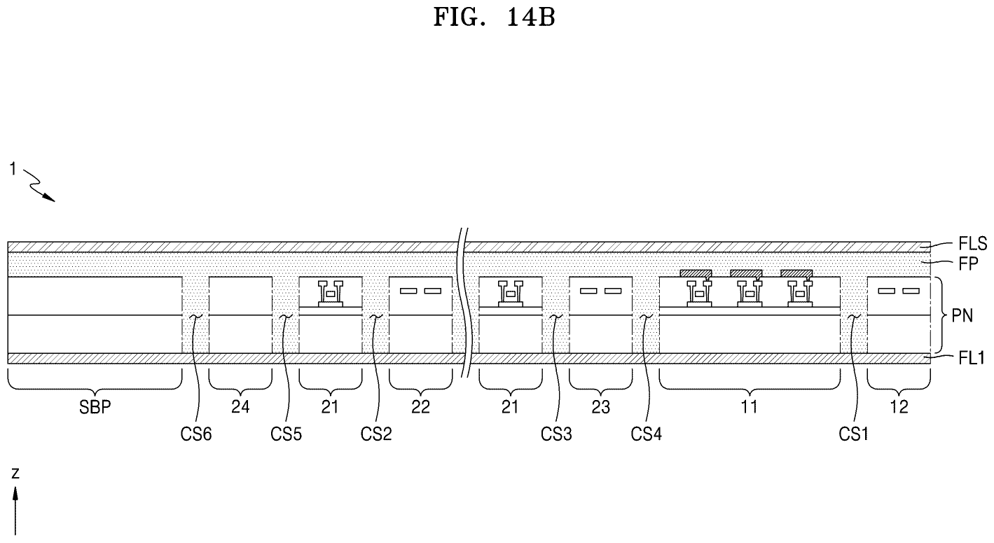

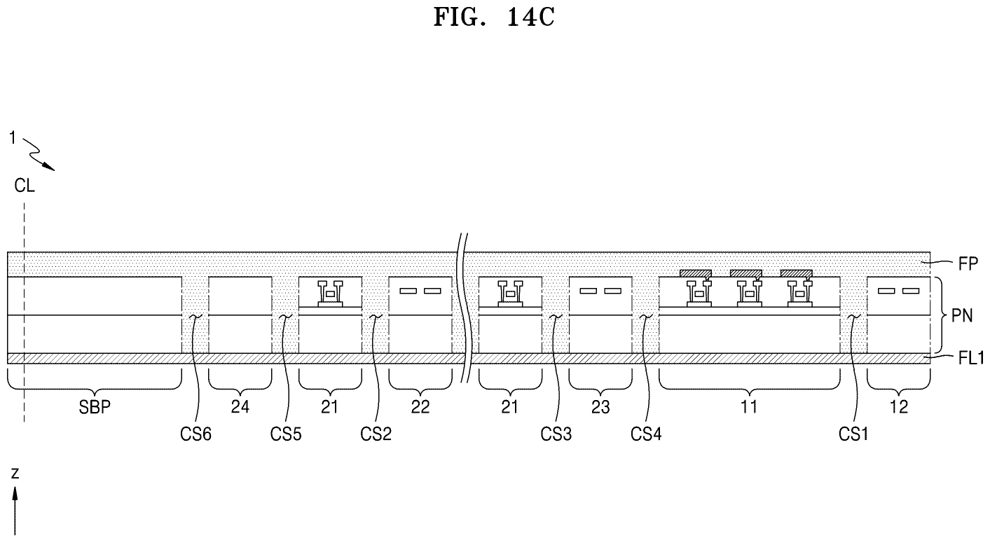

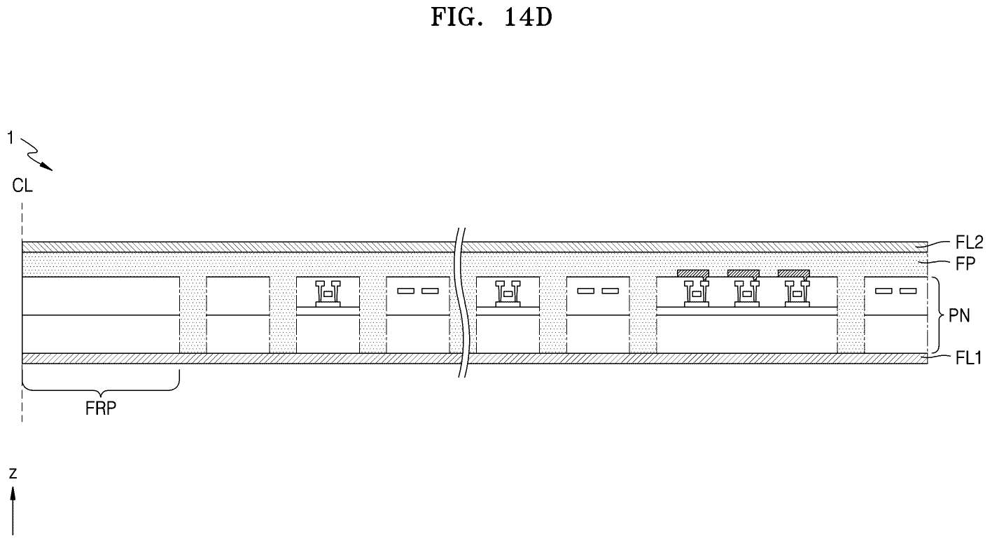

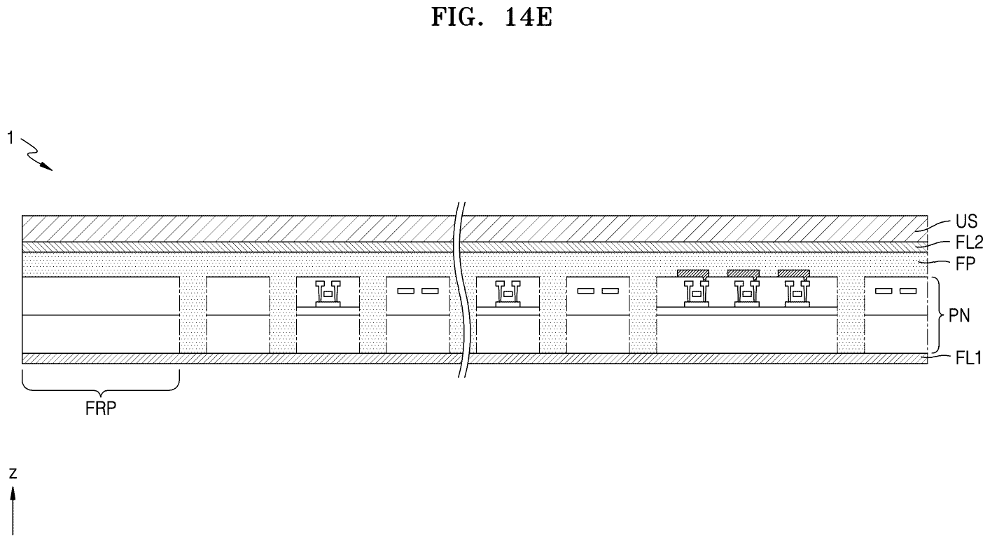

As the support film FLS (refer to FIG. 14C) is removed from the display panel PN, the top surface of the display panel PN may be exposed. The cutting line CL may overlap at least one of the plurality of sawtooth openings OPSB. The cutting line CL may overlap an end ESB of at least one of the plurality of sawtooth openings OPSB. In an embodiment, as shown in FIG. 12E, the cutting line CL may overlap all of the ends ESB of the plurality of sawtooth openings OPSB, for example. That is, the cutting line CL may be the same as a boundary line dividing the plurality of sawtooth portions SBP1 and the connecting portion SBP2.

FIG. 12F is a cross-sectional view of a portion of the stretchable display device 1 after the outer portion SBP is cut along the cutting line CL according to the process described with reference to FIGS. 12D and 12E. Referring to FIGS. 12E and 12F, a portion of the outer portion SBP disposed in the first direction (e.g., −x direction) with respect to the cutting line CL may be removed. That is, a portion of the outer portion SBP disposed outside the cutting line CL may be removed. A frame portion FRP may be formed by removing a portion of the outer portion SBP. By using the first film FL1 disposed below the display panel PN, bending or deformation of the display panel PN may be reduced during the cutting process.

Referring to FIG. 12G, the method of manufacturing the stretchable display device 1 may include disposing an upper substrate US on the display panel PN. The upper substrate US may be disposed on the filling portion FP disposed on the display panel PN.

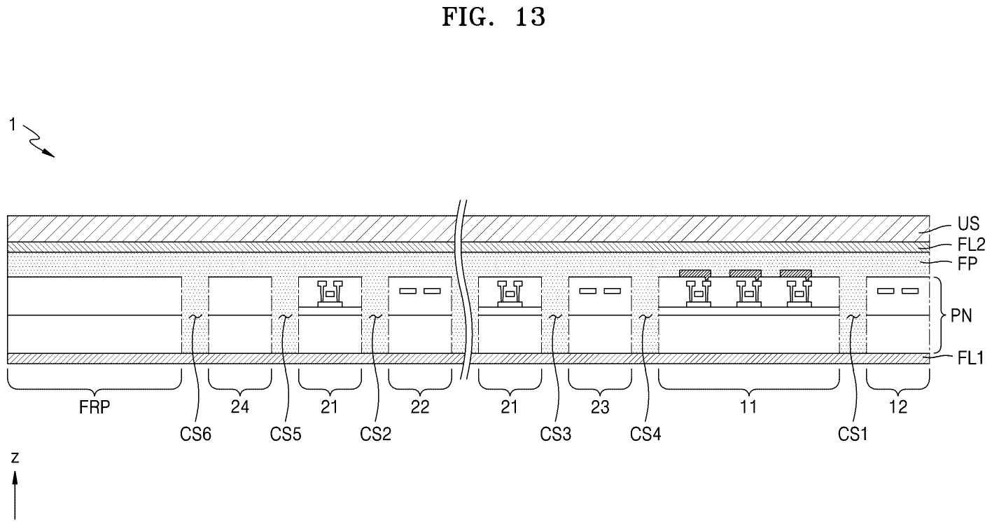

FIG. 13 is a schematic cross-sectional view of an embodiment of a portion of a stretchable display device 1.

In FIG. 13, the same reference numerals as those in FIGS. 8 and 9 refer to the same members as those in FIGS. 8 and 9, and thus, redundant descriptions thereof are omitted.

Referring to FIG. 13, the stretchable display device 1 may include a first film FL1, a display panel PN, a second film FL2, an upper substrate US, and a filling portion FP.

The first film FL1 may include a flexible material that may be stretched.

The display panel PN may be disposed on the first film FL1. The display panel PN may include a flexible material that may be stretched. The display panel PN may display an image by a plurality of pixels. The display panel PN may include a substrate 100, a buffer layer 111, an insulating layer IL, a pixel driving circuit portion PC, a panel driving circuit portion DC, and a wiring line WL. Because the display panel PN has been described above with reference to FIG. 8, detailed descriptions thereof are omitted.

The second film FL2 may be disposed on the display panel PN. The second film FL2 may include a flexible material that may be stretched. The second film FL2 may include the same material as that of the first film FL1. In an embodiment, the second film FL2 may include at least one of PDMS and polyurethane PU, for example.

The upper substrate US may be disposed on the second film FL2. The upper substrate US may include a flexible material that may be stretched.

The filling portion FP may be disposed between the first film FL1 and the second film FL2. The filling portion FP may contact the display panel PN. At least a portion of the filling portion FP may be accommodated in an opening of the display panel PN.

FIGS. 14A to 14E are schematic cross-sectional views of an embodiment of a portion of a stretchable display device 1.

In FIGS. 14A to 14E, the same reference numerals as those in FIGS. 8 and 9 refer to the same members as those in FIGS. 8 and 9, and thus, redundant descriptions thereof are omitted.

Referring to FIGS. 14A to 14E, a method of manufacturing the stretchable display device 1 may be seen.

First, referring to FIG. 14A, the method of manufacturing the stretchable display device 1 may include disposing a display panel PN on a support substrate SS, and disposing a support film FLS on the display panel PN.

The support substrate SS may include glass having a sufficient thickness. The support substrate SS may have sufficient hardness to reduce bending or deformation of the display panel PN including a flexible material during the manufacturing process.

The method of manufacturing the stretchable display device 1 may further include disposing a filling portion FP on the display panel PN before disposing the support film FLS on the display panel PN. In this case, the disposing of the support film FLS on the display panel PN may be disposing the support film FLS on the filling portion FP disposed on the display panel PN.

Referring to FIG. 14B, the method of manufacturing the stretchable display device 1 may include removing the support substrate SS (refer to FIG. 14A) from the display panel PN, and disposing the display panel PN on a first film FL1.

The support film FLS may have a higher modulus than that of the first film FL1. In an embodiment, the support film FLS may include a PET material, for example. Accordingly, in the removing of the support substrate SS (refer to FIG. 14A) from the display panel PN, the support film FLS may reduce bending or deformation of the display panel PN.

When the support substrate SS (refer to FIG. 14A) is removed, the first film FL1 may be attached to a lower portion of the display panel PN. In this process, the support substrate SS (refer to FIG. 14A) may be replaced with the first film FL1. Accordingly, the display panel PN may be disposed on the first film FL1.

Referring to FIGS. 14C and 14D, the method of manufacturing the stretchable display device 1 may include removing the support film FLS (refer to FIG. 14C) from the display panel PN, disposing the second film FL2 on the display panel PN, and cutting the outer portion SBP along a cutting line CL.

As the support film FLS (refer to FIG. 14C) is removed from the display panel PN, the top surface of the display panel PN may be exposed. When the support film FLS (refer to FIG. 14C) is removed, the second film FL2 may be disposed on the display panel PN. That is, disposing the second film FL2 on the display panel PN may be performed between removing the support film FLS from the display panel PN and cutting the outer portion SBP along the cutting line CL.

After the outer portion SBP is cut along the cutting line CL, a portion of the outer portion SBP disposed in a first direction (e.g., −x direction) with respect to the cutting line CL may be removed. That is, a portion of the outer portion SBP disposed outside the cutting line CL may be removed. A frame portion FRP may be formed by removing a portion of the outer portion SBP. By using the first film FL1 disposed below the display panel PN and the second film FL2 disposed above the display panel PN, bending or deformation of the display panel PN may be reduced during the cutting process.

Referring to FIG. 14E, the method of manufacturing the stretchable display device 1 may include disposing an upper substrate US on the second film FL2. The upper substrate US may be disposed on the second film FL2 disposed on the display panel PN.

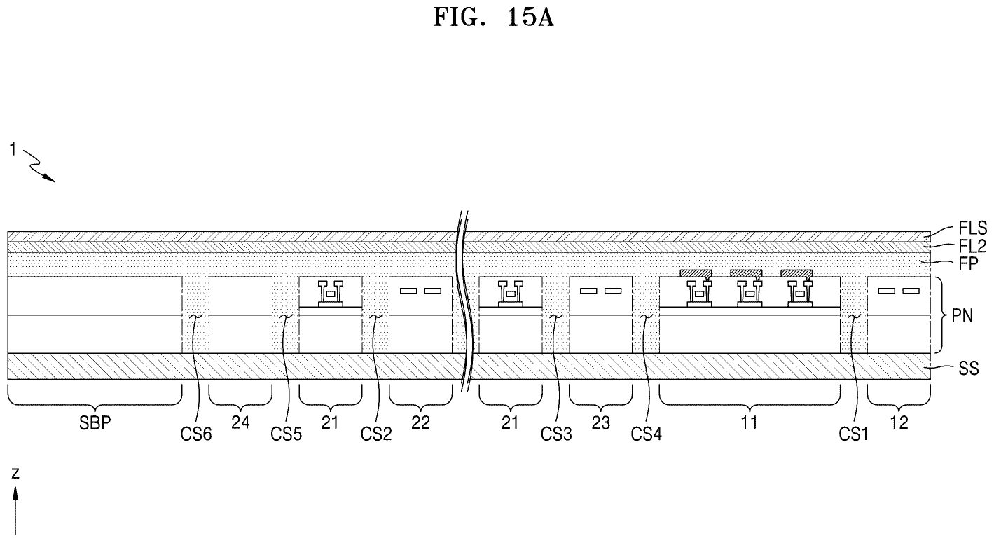

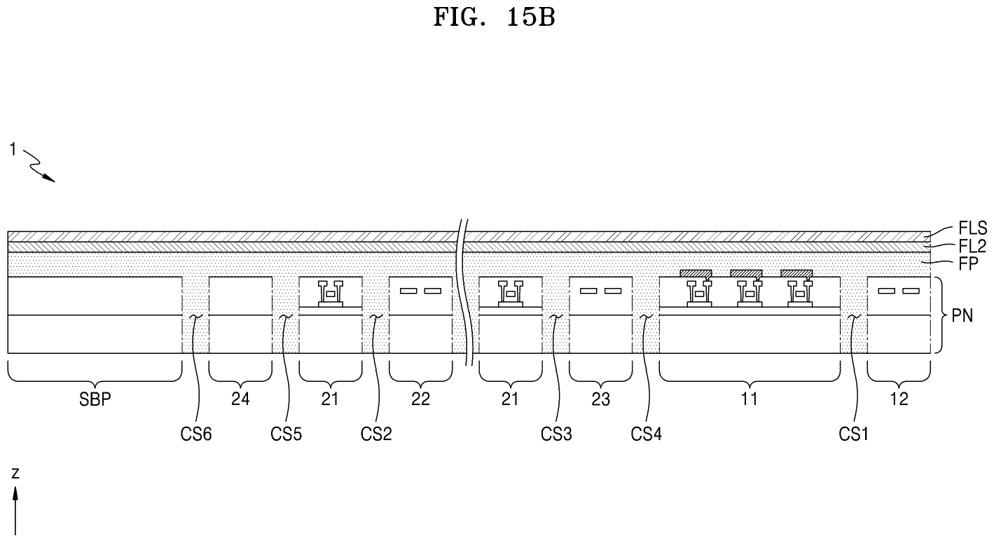

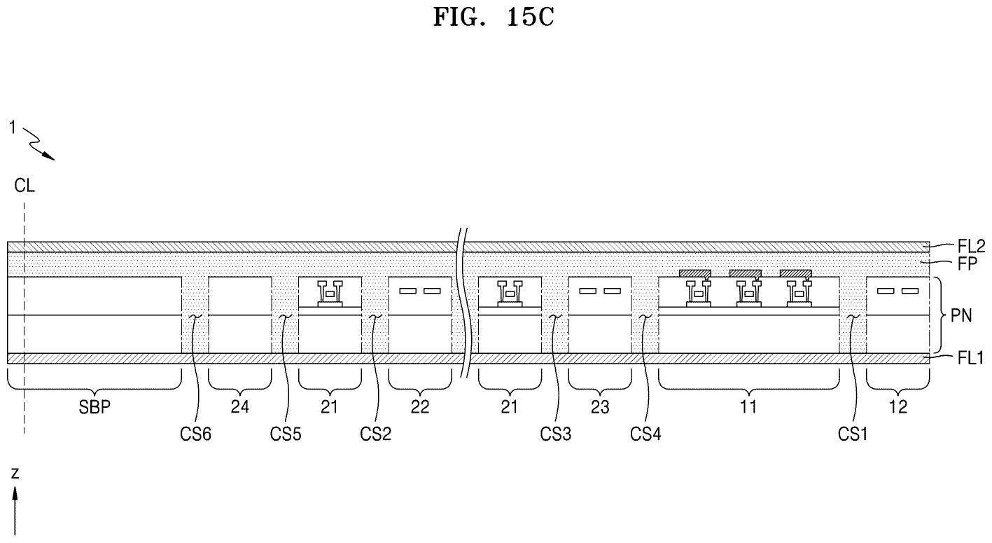

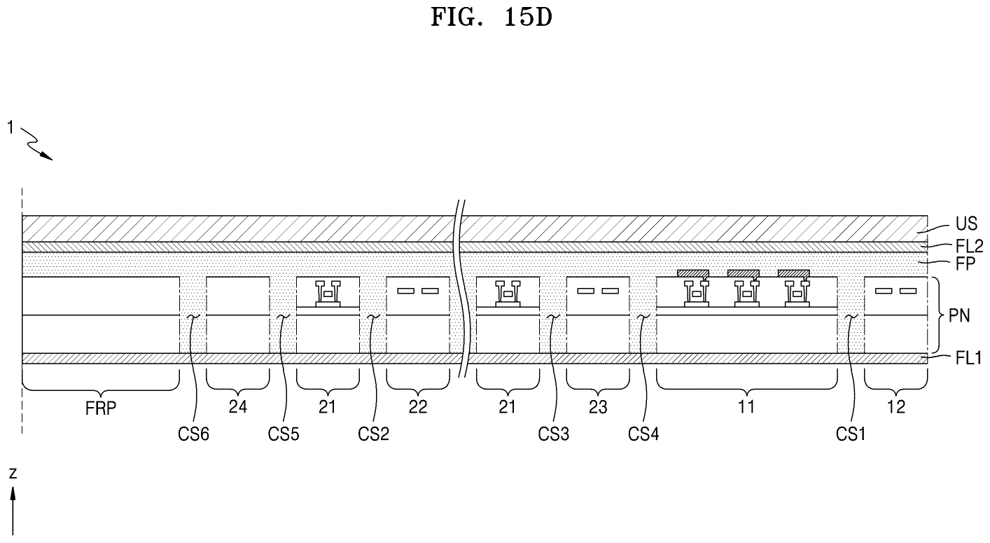

FIGS. 15A to 15D are schematic cross-sectional views of an embodiment of a portion of a stretchable display device 1.

In FIGS. 15A to 15D, the same reference numerals as those in FIGS. 8 and 9 refer to the same members as those in FIGS. 8 and 9, and thus, redundant descriptions thereof are omitted.

Referring to FIGS. 15A to 15D, a method of manufacturing a stretchable display device 1 may be seen.

First, referring to FIG. 15A, the method of manufacturing the stretchable display device 1 may include disposing a display panel PN on a support substrate SS, disposing a second film FL2 on the display panel PN, and disposing a support film FLS on the display panel PN. The disposing of the support film FLS on the display panel PN may be disposing the support film FLS on the second film FL2.

The support substrate SS may include glass having a sufficient thickness. The support substrate SS may have sufficient hardness to reduce bending or deformation of the display panel PN including a flexible material during the manufacturing process.

The method of manufacturing the stretchable display device 1 may further include disposing a filling portion FP on the display panel PN before disposing the second film FL2 on the display panel PN. In this case, the disposing of the second film FL2 on the display panel PN may be disposing the second film FL2 on the filling portion FP disposed on the display panel PN.

Referring to FIG. 15B, the method of manufacturing the stretchable display device 1 may include removing the support substrate SS (refer to FIG. 15A) from the display panel PN, and disposing the display panel PN on a first film FL1.

The support film FLS may have a higher modulus than that of the first film FL1 and the second film FL2. In an embodiment, the support film FLS may include a PET material. Therefore, in the removing of the support substrate SS (refer to FIG. 15A) from the display panel PN, the support film FLS may reduce bending or deformation of the display panel PN, for example.

When the support substrate SS (refer to FIG. 15A) is removed, the first film FL1 may be attached to a lower portion of the display panel PN. In this process, the support substrate SS (refer to FIG. 15A) may be replaced with the first film FL1. Accordingly, the display panel PN may be disposed on the first film FL1.

Referring to FIGS. 15C and 15D, the method of manufacturing the stretchable display device 1 may include removing the support film FLS (refer to FIG. 15C) from the display panel PN, cutting the outer portion SBP along a cutting line CL, and disposing an upper substrate US on the second film FL2.

The removing of the support film FLS (refer to FIG. 15C) from the display panel PN may be removing the support film FLS (refer to FIG. 15C) from the second film FL2. As the support film FLS (refer to FIG. 15C) is removed from the display panel PN, the top surface of the second film FL2 may be exposed.

After the outer portion SBP is cut along the cutting line CL, a portion of the outer portion SBP disposed in a first direction (e.g., −x direction) with respect to the cutting line CL may be removed. That is, a portion of the outer portion SBP disposed outside the cutting line CL may be removed. A frame portion FRP may be formed by removing a portion of the outer portion SBP. By using the first film FL1 disposed below the display panel PN and the second film FL2 disposed above the display panel PN, bending or deformation of the display panel PN may be reduced during the cutting process. The upper substrate US may be disposed on the second film FL2 disposed on the display panel PN.

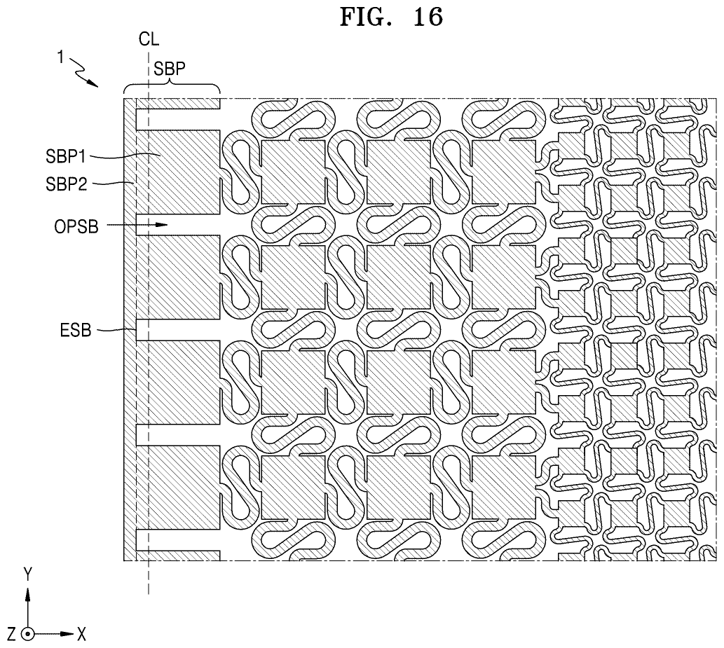

FIG. 16 is a schematic plan view of an embodiment of a portion of a stretchable display device 1.

In FIG. 16, the same reference numerals as those in FIGS. 8 and 9 refer to the same members as those in FIGS. 8 and 9, and thus, redundant descriptions thereof are omitted.

Specifically, FIG. 16 is a schematic plan view of a portion of the stretchable display device 1 before an outer portion SBP is cut along a cutting line CL.

Referring to FIG. 16, the cutting line CL may be spaced apart from at least one of the ends ESB of a plurality of sawtooth openings OPSB. The cutting line CL may be disposed to be spaced apart from at least one of the ends ESB of the plurality of sawtooth openings OPSB in a first direction (e.g., x direction). That is, the cutting line CL may be disposed to be spaced apart from a connecting portion in the first direction (e.g., x-direction). Therefore, in the process of cutting the outer portion SBP, a margin for a plurality of sawtooth portions SBP1 to be stably separated from each other may be secured.

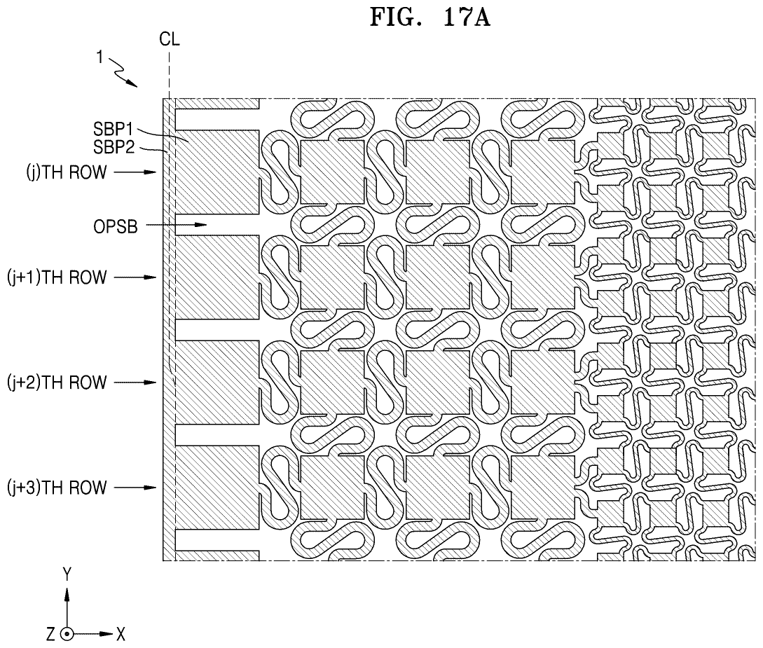

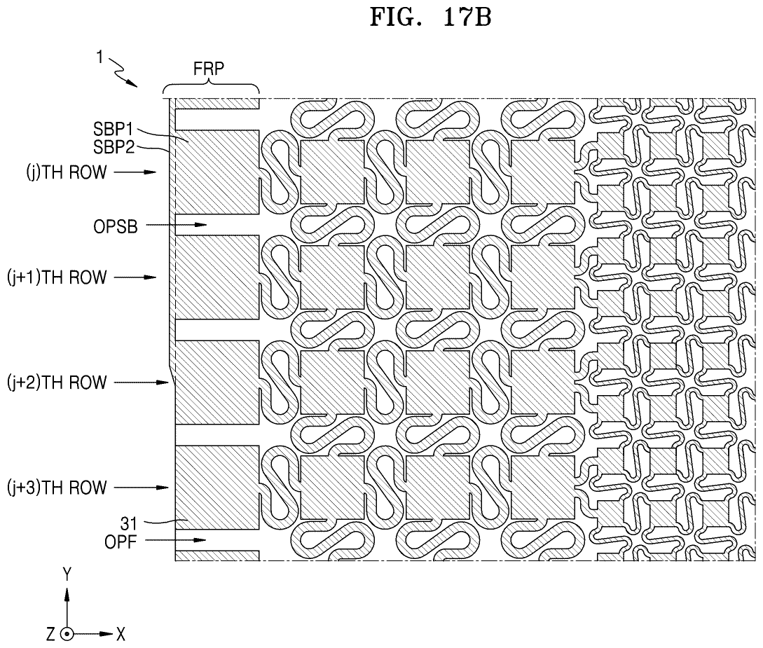

FIGS. 17A and 17B are schematic plan views of an embodiment of a portion of a stretchable display device 1.

In FIGS. 17A and 17B, the same reference numerals as those in FIGS. 8 and 9 refer to the same members as those in FIGS. 8 and 9, and thus, redundant descriptions thereof are omitted.

Specifically, FIG. 17A is a schematic plan view of a portion of the stretchable display device 1 before an outer portion SBP is cut along a cutting line CL, and FIG. 17B is a schematic plan view of a portion of the stretchable display device 1 in a state in which the outer portion SBP is cut along the cutting line CL to form a frame portion FRP.

Referring to FIG. 17A, the cutting line CL may be spaced apart from at least one of the plurality of sawtooth openings OPSB. One or more sawtooth openings OPSB may be spaced apart from the cutting line CL, and one or more other sawtooth openings OPSB may overlap the cutting line CL. In an embodiment, as shown in FIG. 17A, the cutting line CL may be spaced apart from sawtooth openings OPSB adjacent to sawtooth portions SBP1 arranged in the (j)th row, (j+1)th row, and (j+2)th row, for example. In addition, the cutting line CL may overlap a sawtooth opening OPSB adjacent to a sawtooth portion SBP1 disposed in the (j+3)th row.

Referring to FIG. 17B, after cutting, a portion of a connecting portion SBP2 extended to two or more sawtooth portions SBP1 to each other may remain. Accordingly, two or more sawtooth portions SBP1 extended to the remaining connecting portion SBP2 may not be separated from each other. That is, at least one of the plurality of third island portions may include a plurality of sawtooth portions and a connecting portion. In an embodiment, the sawtooth portions SBP1 arranged in the (j)th row, (j+1)th row, and (j+2)th row and the remaining connecting portion SBP2 may form one third island portion 31, for example. In addition, a third island portion 31 may be formed in the (j+3)th row. That is, the shapes of at least two of the plurality of third island portions 31 may be different from each other.

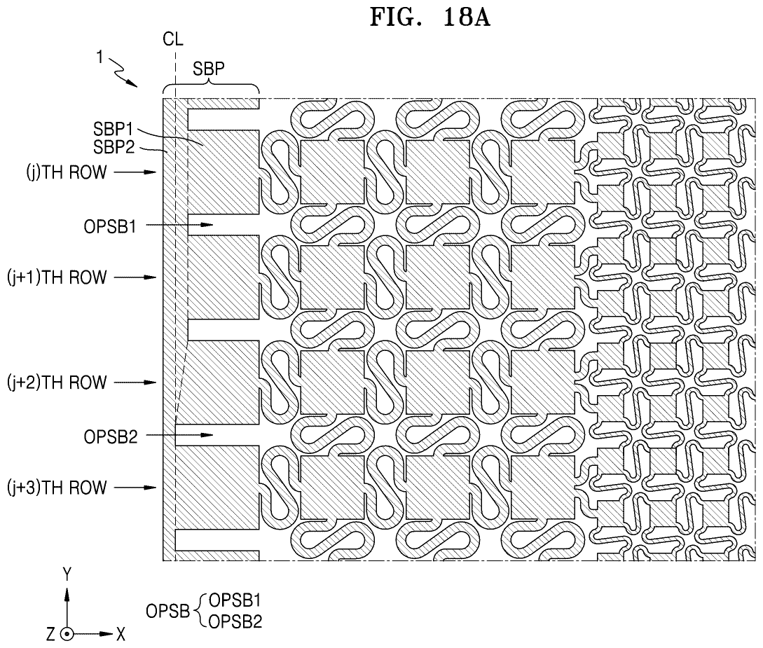

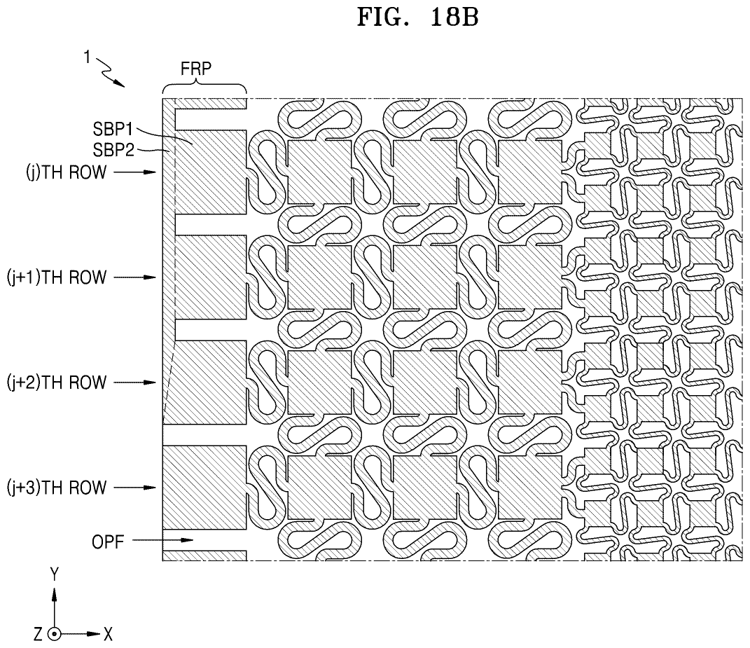

FIGS. 18A and 18B are schematic plan views of an embodiment of a portion of a stretchable display device 1.

In FIGS. 18A and 18B, the same reference numerals as those in FIGS. 8 and 9 refer to the same members as those in FIGS. 8 and 9, and thus, redundant descriptions thereof are omitted.

Specifically, FIG. 18A is a schematic plan view of a portion of the stretchable display device 1 before an outer portion SBP is cut along a cutting line CL, and FIG. 18B is a schematic plan view of a portion of the stretchable display device 1 in a state in which the outer portion SBP is cut along the cutting line CL to form a frame portion FRP.

Referring to FIG. 18A, a plurality of sawtooth openings OPSB may include one or more first sawtooth openings OPSB1 and one or more second sawtooth openings OPSB2. The shape of the first sawtooth opening OPSB1 and the shape of the second sawtooth opening OPSB2 may be different from each other. The length of the second sawtooth opening OPSB2 in a first direction (e.g., x direction and/or −x direction) may be greater than the length of the first sawtooth opening OPSB1.

In an embodiment, the length of a sawtooth opening OPSB (e.g., the first sawtooth opening OPSB1) adjacent to the sawtooth portion SBP1 disposed in the (j)th row and the (j+1)th row, in the first direction (e.g., x direction and/or −x direction), may be less than the length of a sawtooth opening OPSB (e.g., the second sawtooth opening OPSB2) adjacent to the sawtooth portion SBP1 disposed in the (j+3)th row. In addition, the lengths of two sawtooth openings OPSB adjacent to the sawtooth portion SBP1 disposed in the (j+2)th row, in the first direction (e.g., x direction and/or −x direction) may be different from each other, for example.

The cutting line CL may be spaced apart from the first sawtooth opening OPSB1 and may overlap the second sawtooth opening OPSB2. In an embodiment, the cutting line CL may be spaced apart from a sawtooth opening OPSB (e.g., the first sawtooth opening OPSB1) adjacent to the sawtooth portion SBP1 disposed in the (j)th row and the (j+1)th row. In addition, the cutting line CL may overlap a sawtooth opening OPSB (e.g., the second sawtooth opening OPSB2) adjacent to the sawtooth portion SBP1 disposed in the (j+3)th row. In addition, the cutting line CL may be spaced apart from one (e.g., the first sawtooth opening OPSB1) of two sawtooth openings OPSB adjacent to the sawtooth portion SBP1 disposed d in the (j+2)th row and may overlap the other, for example.

Referring to FIG. 18B, after cutting, a portion of a connecting portion SBP2 extended to two or more sawtooth portions SBP1 to each other may remain. Accordingly, two or more sawtooth portions SBP1 extended to the remaining connecting portion SBP2 may not be separated from each other. That is, at least one of the plurality of third island portions 31 may include a plurality of sawtooth portions SBP1 and a connecting portion SBP2. In an embodiment, the sawtooth portions SBP1 arranged in the (j)th row, (j+1)th row, and (j+2)th row and the remaining connecting portion SBP2 may form one third island portion 31. In addition, a third island portion 31 may be formed in the (j+3)th row, for example.

The stretchable display device 1 in the embodiments described above may be used in various electronic devices capable of providing images. In this case, the electronic devices refer to devices that use electricity and may provide a predetermined image.

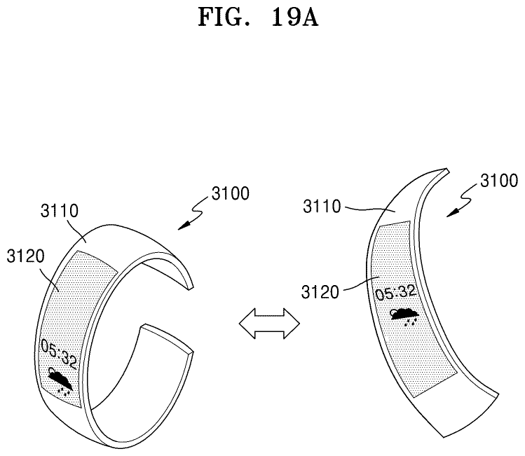

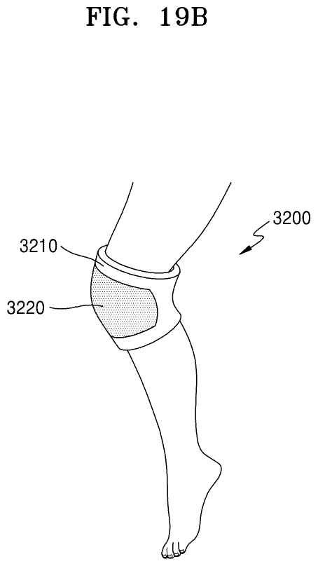

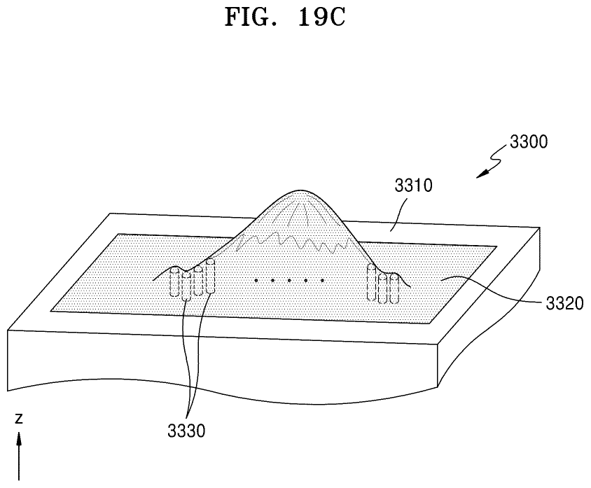

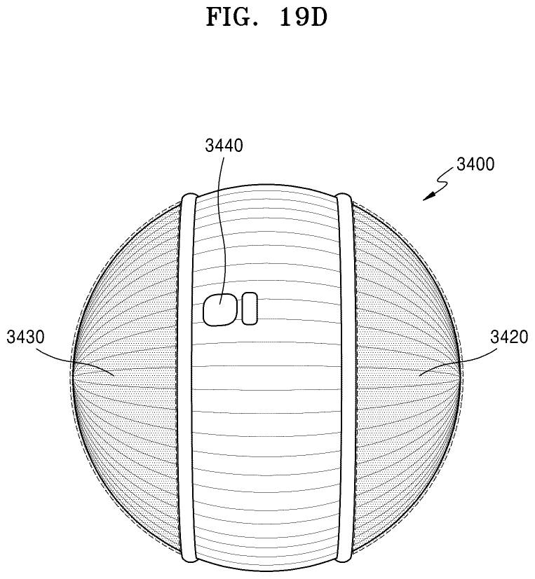

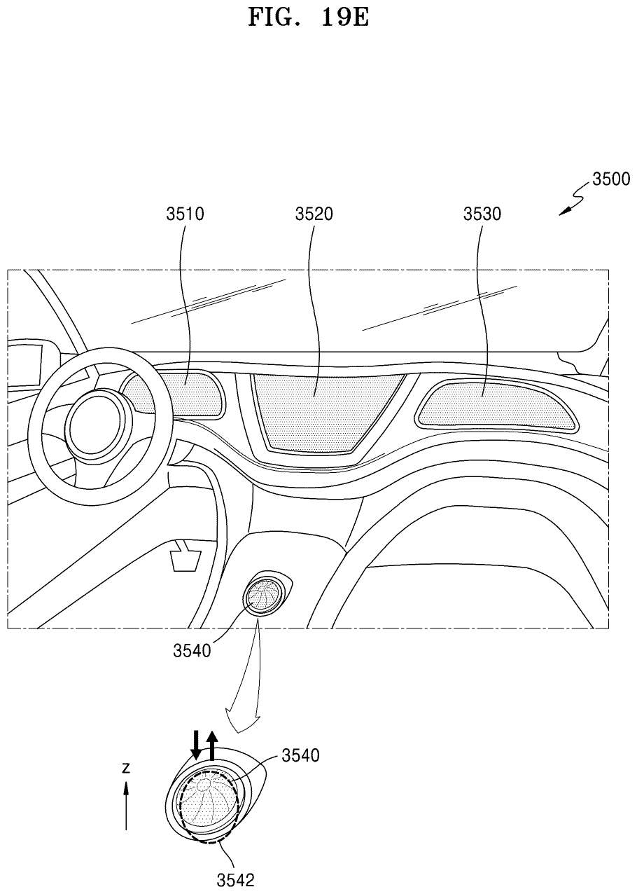

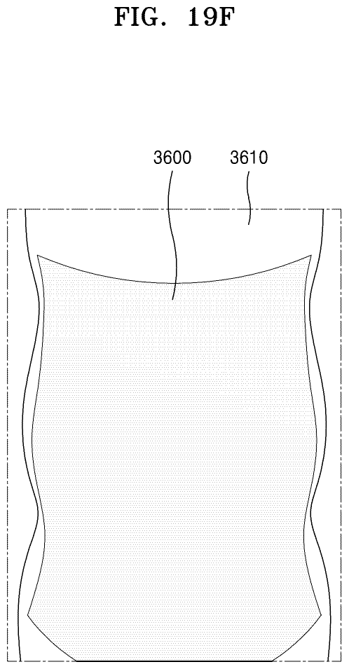

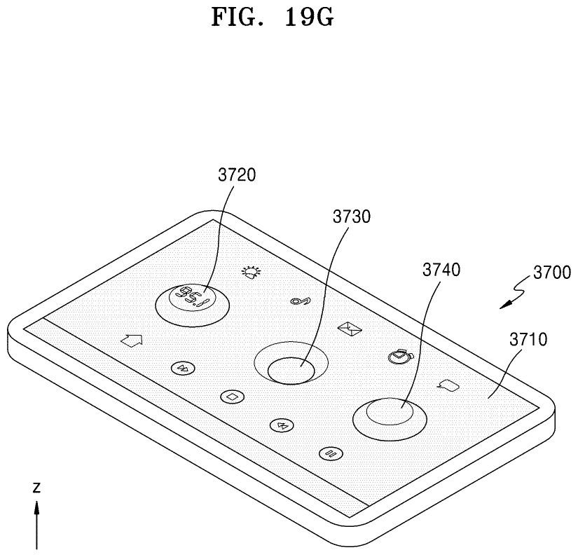

FIGS. 19A to 19G are perspective views schematically showing embodiments of an electronic device including a stretchable display device.

Referring to FIG. 19A, the stretchable display device in an embodiment may be used in a wearable electronic device 3100 that may be worn on a portion of a user's body. The wearable electronic device 3100 may include a body portion 3110 and a display portion 3120 provided on the body portion 3110. The stretchable display device in an embodiment may be used as the display portion 3120 of the wearable electronic device 3100. As shown in FIG. 19A, the wearable electronic device 3100 may be deformable. In an embodiment, the wearable electronic device 3100 may be used as a smart watch or a smartphone depending on a user's choice.

FIG. 19B shows a medical electronic device 3200. In an embodiment, the medical electronic device 3200 may include a body portion 3210 and a light-emitting portion 3220. The stretchable display device in an embodiment may be used as the light-emitting portion 3220 of the medical electronic device 3200. The light-emitting portion 3220 may emit light (e.g., infrared light or visible light) of a predetermined wavelength band to a patient's body. In an embodiment, the body portion 3210 may include a stretchable fiber material and may have a structure in which the body portion 3210 may be worn on a user's body.

FIG. 19C shows an educational electronic device 3300. In an embodiment, the educational electronic device 3300 may include a display portion 3320 provided within a frame 3310. In an embodiment, the display portion 3320 may use a stretchable display device. The display portion 3320 may provide images, such as an ocean with waves, a snow-covered mountain, or a volcano with flowing lava, and in this case, the display portion 3320 may be stretched in a height direction (e.g., z direction) to reflect the height of waves, mountains, or volcanoes. In some embodiments, a portion of the display portion 3320 may show the movement of lava in three dimensions by sequentially changing the height in a direction in which the lava flows. The educational electronic device 3300 may include a plurality of pins (or stroke portions) 3330 disposed on the back of the display portion 3320 so that the display portion 3320 is stretched in the height direction. As the pins 3330 move in a third direction (e.g., z direction or −z direction), the image displayed on the display portion 3320 may be implemented to have a three-dimensional height. FIG. 19C illustrates the educational electronic device 3300, but its use is not limited as long as it provides predetermined image information.

Although the electronic device shown in FIGS. 19A to 19C is described as an electronic device whose shape may be variable, but the disclosure is not limited thereto. As in embodiments to be described below, the stretchable display device in embodiments may be used in an electronic device in which a part (e.g., a screen) capable of displaying an image is fixed.

FIG. 19D shows a robot 3400 as another electronic device. The robot 3400 may recognize movement or objects by a camera portion 3440 and may display a predetermined image to a user through display portions 3420 and 3430. In some embodiments, the stretchable display device in an embodiment may be stretched in various directions as described above and thus may be assembled into a body frame having a hemispherical shape, and thus, the robot 3400 may include the display portions 3420 and 3430 having hemispherical shapes.

FIG. 19E shows a vehicle display device 3500 as another electronic device. The vehicle display device 3500 may include a cluster 3510, a center information display (“CID”) 3520, and/or a passenger seat display 3530. Because the stretchable display device in an embodiment may be stretched in various directions, the stretchable display device may be used in the cluster 3510, the CID 3520, and/or a co-driver display (i.e., the passenger seat display) 3530 regardless of the shape of a vehicle's internal frame.

Although FIG. 19E shows the cluster 3510, the CID 3520, and/or the co-driver display 3530 being separated, the disclosure is not limited thereto. In another embodiment, two or more selected from the cluster 3510, the CID 3520, and the co-driver display 3530 may be integrally connected.

In some embodiments, the vehicle display device 3500 may include a button 3540 that may display a predetermined image. Referring to the enlarged view of FIG. 19E, the button 3540 having a hemispherical shape may include an object 3542 that provides the feeling of using the button 3540 while moving in a z direction or-z direction, and a stretchable display device disposed on the object 3542. In some embodiments, when the object 3542 has a three-dimensionally rounded surface, the stretchable display device may also have a three-dimensionally rounded surface.

FIG. 19F shows that the electronic device in an embodiment is an electronic device 3600 for advertising or exhibition. In some embodiments, the electronic device 3600 for advertising or exhibition may be installed on a fixed structure 3610, such as a wall or pillar. When the structure 3610 includes an uneven surface as shown in FIG. 19F, the electronic device 3600 for advertising or exhibition may also be disposed along the uneven surface of the structure 3610. In some embodiments, the electronic device 3600 for advertising or exhibition may be installed on the structure 3610 by a heat-shrink film or the like.

FIG. 19G shows that the electronic device in an embodiment is a controller 3700. The controller 3700 may include image-type buttons. In an embodiment, the controller 3700 may include first to third button areas 3720, 3730, and 3740 in which a portion of a display portion 3710 protrudes in a z direction or protrudes in a −z direction (or is dented in the z direction), for example. In some embodiments, the first and third button areas 3720 and 3740 may protrude in the z direction, and the second button area 3730 may protrude in the −z direction (or be dented in the z direction).

In an embodiment, a display device, which may prevent damage due to concentration of stress and may expand and contract in various directions, may be provided.

In an embodiment, a method of manufacturing a display device including a stretchable frame portion through a simple and stable process may be provided.

The aforementioned effects are exemplary, and the scope of the disclosure is not limited by these effects.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A display device comprising:
a first film; and
a display panel disposed on the first film and including:
a display portion including a plurality of first island portions spaced apart from each other and including light-emitting elements;
a driver portion including a plurality of second island portions which are spaced apart from each other, and on which drivers which provide electrical signals to the light-emitting elements are arranged; and
a frame portion including a plurality of third island portions spaced apart from each other in a second direction crossing a first direction in which the display portion, the driver portion and the frame portion are sequentially arranged,
wherein an elongation rate of the display portion, an elongation rate of the driver portion, and an elongation rate of the frame portion are different from each other.

2. The display device of claim 1, wherein the elongation rate of the driver portion is greater than the elongation rate of the frame portion in the first direction.

3. The display device of claim 1, wherein the elongation rate of the frame portion is greater than the elongation rate of the driver portion in the second direction.

4. The display device of claim 1, wherein one of the plurality of second island portions is extended to one of the plurality of third island portions.

5. The display device of claim 1, wherein at least two of the plurality of second island portions are extended to one of the plurality of third island portions.

6. The display device of claim 1, wherein different numbers of second island portions among the plurality of second island portions are extended to at least two of the plurality of third island portions.

7. The display device of claim 1, wherein, with respect to a center line between two adjacent third island portions of the plurality of third island portions, two adjacent second island portions of the plurality of second island portions are symmetrical to each other.

8. The display device of claim 1, wherein at least two of the plurality of third island portions have different shapes from each other.

9. The display device of claim 1, wherein at least one of the plurality of third island portion portions includes:
a plurality of sawtooth portions spaced apart from each other in the second direction; and
a connecting portion extended from the plurality of sawtooth portions in the first direction so that the plurality of sawtooth portions is extended to each other.

10. The display device of claim 1, wherein a length of each of third island portions in the second direction among the plurality of third island portions is greater than a length of each of second island portions in the second direction among the plurality of second island portions.

11. The display device of claim 1, wherein the first film includes at least one of polydimethylsiloxane and polyurethane.

12. The display device of claim 1, further comprising a second film disposed on the display panel.

13. The display device of claim 12, wherein the second film includes a same material as a material of the first film.

14. A method of manufacturing a display device, the method comprising:
disposing, on a support substrate, a display panel including a display portion, a driver portion, and an outer portion, which are sequentially arranged in a first direction;
disposing a support film on the display panel;
removing the support substrate from the display panel;
disposing the display panel on a first film;
removing the support film from the display panel; and
cutting the outer portion along a cutting line,
wherein the outer portion includes:
a plurality of sawtooth portions spaced apart from each other in a second direction crossing the first direction; and
a connecting portion extended from the plurality of sawtooth portions in the first direction so that the plurality of sawtooth portions is extended to each other,
wherein the cutting line overlaps at least one of a plurality of sawtooth openings defining a space between the plurality of sawtooth portions.

15. The method of claim 14, wherein the cutting line overlaps an end of at least one of the plurality of sawtooth openings.

16. The method of claim 14, wherein the cutting line is spaced apart from at least one of the plurality of sawtooth openings.

17. The method of claim 14, wherein the plurality of sawtooth openings include a first sawtooth opening and a second sawtooth opening having a length greater in the first direction than a length of the first sawtooth opening.

18. The method of claim 17, wherein the cutting line is spaced apart from the first sawtooth opening and overlaps the second sawtooth opening.

19. The method of claim 14, wherein the first film includes at least one of polydimethylsiloxane and polyurethane.

20. The method of claim 14, wherein the support film has a higher modulus than a modulus of the first film.

21. The method of claim 20, wherein the support film includes a polyethylene terephthalate (“PET”) material.

22. The method of claim 14, further comprising arranging a second film on the display panel.

23. The method of claim 22, wherein the arranging the second film on the display panel is performed between the removing the support film from the display panel and the cutting of the outer portion along the cutting line.

24. The method of claim 22, wherein the arranging the support film on the display panel includes arranging the support film on the second film.

25. The method of claim 22, wherein the second film includes a same material as a material of the first film.
